(19) United States
(12) Patent Application Publication
(10) Pub. No.: US 2024/0213130 A1
(43) Pub. Date: Jun. 27, 2024

(54) COMPOUND COMPONENT DEVICE AND METHOD OF MANUFACTURING THE SAME

(71) Applicant: Murata Manufacturing Co., Ltd., Kyoto-fu (JP)

(72) Inventor: Wataru DOI, Nagaokakyo-shi (JP)

(73) Assignee: Murata Manufacturing Co., Ltd., Kyoto-fu (JP)

(21) Appl. No.: 18/494,611

(22) Filed: Oct. 25, 2023

(30) Foreign Application Priority Data
Dec. 22, 2022 (JP) 2022-205845

(51) Int. Cl. H01L 23/498; H01L 23/00; H01L 23/31; H01L 25/065

(52) U.S. Cl. CPC H01L 23/49822; H01L 23/3107; H01L 23/49838; H01L 23/49894; H01L 24/16; H01L 24/32; H01L 24/73; H01L 25/0655; H01L 2224/16225; H01L 2224/32225; H01L 2224/73153; H01L 2924/181

(57) ABSTRACT

A compound component device including laminated first compound component layers housing first electronic components, in which the first compound component layers each include an electronic component layer, including a first main surface and a second main surface opposed to the first main surface, and a redistribution layer provided on the first main surface. At least two of the plurality of first compound component layers configure an inverted layer for which the first compound component layers are paired and formed so that the second main surfaces face each other. The electronic component layer includes the first electronic component, a first resin sealing portion to seal the first electronic component, a side wall portion that encloses the first electronic component, and electronic component layer piercing vias which pierce the side wall portion and electrically connect with the redistribution layer, and the first electronic component is directly joined to the redistribution layer.

### CROSS-REFERENCE TO RELATED APPLICATION

This application claims benefit of priority to Japanese Patent Application No. 2022-205845, filed Dec. 22, 2022, the entire content of which is incorporated herein by reference.

### BACKGROUND

### Technical Field

The present disclosure relates to a compound component device and a method of manufacturing the compound component device.

### Background Art

Conventional vertically stacked system in package structures include a vertical stack system in package (vertical stack SiP) disclosed in FIG. 10 of Japanese Unexamined Patent Application Publication (Translation of PCT Application) No. 2018-514088, for instance. The vertical stack SiP includes first to third level molding compounds (125, 155, 185), first to third redistribution layers (130, 160, 190) placed therebetween, and second and third level conductive pillars (140, 170) to make electrical connections between the first to third redistribution layers (130, 160, 190). Dies (electronic components) (110, 142, 172) are sealed in the respective molding compounds (125, 155, 185). The pair of dies (142) is stacked back to back in the second molding compound (155).

### SUMMARY

Meanwhile, the inventor found that such a vertical stack SiP as described above had problems as follows. That is, in the second molding compound (155) in which the pair of dies (142) is stacked back to back, there is a fear that increase in amount of resin due to lamination of the dies (142) in a vertical direction may cause increase in internal stresses in the second molding compound (155) which may cause a warpage.

Additionally, the vertical stack SiP is manufactured with sequential stacking of the molding compounds. Heating that is carried out for formation of each of the molding compounds makes heat in a package resist being released and makes the dies (142) prone to undergo thermal damage. Then, the thermal damage is accumulated without alteration and thus there is a fear that deterioration of the dies and decrease in lives of components may cause decrease in long-term reliability of the vertical stack SiP.

Further, the heating is carried out for the formation of each of the molding compounds as described above and thus the molding compounds that have been already formed are heated a plurality of times. Thus, there is a fear that the long-term reliability of the vertical stack SiP may be decreased by accumulation of thermal history.

Therefore, the present disclosure provides a compound component device by which occurrence of a warpage can be curbed. Also, the present disclosure provides a method of manufacturing a compound component device by which occurrence of a warpage may be curbed and which has high long-term reliability.

The inventor diligently conducted investigations in view of the above problems and has obtained a finding that, in a compound component device including a plurality of first compound component layers, a stress which occurs in a first compound component layer can be canceled out by a stress which occurs in an adjoining first compound component layer. Based on such a technical finding, the present disclosure including an inverted layer for which a plurality of first compound component layers are paired so as to face each other has been conceived. That is, the present disclosure includes following aspects.

A compound component device according to an aspect of the present disclosure is a compound component device including a plurality of laminated first compound component layers housing first electronic components. The first compound component layers each include an electronic component layer, including a first main surface and a second main surface opposed to the first main surface, and a redistribution layer provided on the first main surface. At least two of the plurality of first compound component layers configure an inverted layer for which the first compound component layers are paired and formed so that the second main surfaces face each other. The electronic component layer includes the first electronic component, a first resin sealing portion to seal the first electronic component, a side wall portion that is placed so as to enclose the first electronic component, and electronic component layer piercing vias to pierce the side wall portion and to electrically connect with the redistribution layer, and the first electronic component is directly joined to the redistribution layer.

In the compound component device according to the aspect of the present disclosure, the plurality of first compound component layers configure the inverted layer for which the first compound component layers are paired and placed so that the second main surfaces of the first compound component layers face each other. Such configuration of the inverted layers by a set of first compound component layers enables separation of a resin sealing portion into two portions. Thus, internal stresses can be reduced, so that occurrence of a warpage in the entire compound component device can be curbed.

Further, the configuration of the inverted layer by the set of first compound component layers makes the internal stresses which occur in the first compound component layers in the inverted layer prone to have opposite directions and thus makes the internal stresses in the inverted layer prone to be canceled out, so that the occurrence of a warpage in the entire compound component device is curbed.

Accordingly, the compound component device according to the present aspect is capable of curbing the occurrence of a warpage.

A method of manufacturing a compound component device according to another aspect of the present disclosure is a method of manufacturing the above-described compound component device. The method includes an electronic component bonding step of bonding the first electronic component onto a silicon base layer so that component electrodes of the first electronic component come into contact with a bottom surface portion of the silicon base layer having a grid-like side wall portion and the bottom surface portion, with an electronic component bonding layer interposed therebetween. The method also includes an electronic component sealing step of forming a resin sealing portion by sealing of the first electronic component with resin; an electronic component layer precursor producing step of producing an electronic component layer precursor by removal of the silicon base layer and the electronic component bonding layer such that entirety of surfaces of the component electrodes is exposed; and an electronic component layer precursor bonding step of producing a pair of electronic component layer precursors by bonding of the two electronic component layer precursors such that main surfaces of the two electronic component layer precursors on which the component electrodes are not exposed face each other. The method further includes an inverted layer precursor producing step of producing an inverted layer precursor by formation of electronic component layer piercing vias that pierce the side wall portions of the pair of electronic component layer precursors and a redistribution layer on one main surface of the pair of electronic component layer precursors on which the component electrodes are exposed; and an inverted layer producing step of forming an inverted layer by formation of a redistribution layer on the other main surface of the inverted layer precursor that is located on a side opposed to the one main surface. In addition, the method includes a laminating step of laminating the pair of electronic component layer precursors produced separately and one of the electronic component layer precursors produced separately on the redistribution layer of the inverted layer precursor; and an interconnection forming step of forming electronic component layer piercing vias and a redistribution layer in or on the laminated pair of electronic component layer precursors and the laminated one of the electronic component layer precursors. A step in which the laminating step and the interconnection forming step are combined is carried out zero or more times.

In the method of manufacturing the compound component device according to the present aspect, the electronic component layer precursors can be machined in parallel. Therefore, the inverted layer or the compound component layers that have been laminated in the laminating step and the interconnection forming step resist accumulation of thermal history. Thus, deterioration of the electronic components can be curbed by curbing on thermal damage to the electronic components.

Accordingly, the method of manufacturing the compound component device according to the present aspect is capable of providing the compound component device having high long-term reliability.

According to the compound component device of the aspect of the present disclosure, the occurrence of a warpage can be curbed. According to the method of manufacturing the compound component device of the other aspect of the present disclosure, the compound component device having high long-term reliability can be manufactured.

### BRIEF DESCRIPTION OF THE DRAWINGS

FIG. 1 is a sectional view illustrating a compound component device according to a first embodiment;

FIG. 2 is an enlarged view of a portion A of FIG. 1;

FIG. 3 is a sectional view along I-I of FIG. 1;

FIG. 4A is an explanatory diagram for description of a method of manufacturing the compound component device according to the first embodiment;

FIG. 4B is an explanatory diagram for the description of the method of manufacturing the compound component device according to the first embodiment;

FIG. 4C is an explanatory diagram for the description of the method of manufacturing the compound component device according to the first embodiment;

FIG. 4D is an explanatory diagram for the description of the method of manufacturing the compound component device according to the first embodiment;

FIG. 4E is an explanatory diagram for the description of the method of manufacturing the compound component device according to the first embodiment;

FIG. 4F is an explanatory diagram for the description of the method of manufacturing the compound component device according to the first embodiment;

FIG. 4G is an explanatory diagram for the description of the method of manufacturing the compound component device according to the first embodiment;

FIG. 4H is an explanatory diagram for the description of the method of manufacturing the compound component device according to the first embodiment;

FIG. 4I is an explanatory diagram for the description of the method of manufacturing the compound component device according to the first embodiment;

FIG. 4J is an explanatory diagram for the description of the method of manufacturing the compound component device according to the first embodiment;

FIG. 4K is an explanatory diagram for the description of the method of manufacturing the compound component device according to the first embodiment;

FIG. 4L is an explanatory diagram for the description of the method of manufacturing the compound component device according to the first embodiment;

FIG. 4M is an explanatory diagram for the description of the method of manufacturing the compound component device according to the first embodiment;

FIG. 4N is an explanatory diagram for the description of the method of manufacturing the compound component device according to the first embodiment;

FIG. 4O is an explanatory diagram for the description of the method of manufacturing the compound component device according to the first embodiment;

FIG. 4P is an explanatory diagram for the description of the method of manufacturing the compound component device according to the first embodiment;

FIG. 5 is a sectional view illustrating a compound component device according to a second embodiment;

FIG. 6A is an explanatory diagram for description of a method of manufacturing the compound component device according to the second embodiment;

FIG. 6B is an explanatory diagram for the description of the method of manufacturing the compound component device according to the second embodiment;

FIG. 6C is an explanatory diagram for the description of the method of manufacturing the compound component device according to the second embodiment;

FIG. 6D is an explanatory diagram for the description of the method of manufacturing the compound component device according to the second embodiment;

FIG. 7 is a sectional view illustrating a compound component device according to a third embodiment;

FIG. 8A is an explanatory diagram for description of a method of manufacturing the compound component device according to the third embodiment;

FIG. 8B is an explanatory diagram for the description of the method of manufacturing the compound component device according to the third embodiment;

FIG. 8C is an explanatory diagram for the description of the method of manufacturing the compound component device according to the third embodiment;

FIG. 8D is an explanatory diagram for the description of the method of manufacturing the compound component device according to the third embodiment;

FIG. 8E is an explanatory diagram for the description of the method of manufacturing the compound component device according to the third embodiment;

FIG. 9A is an explanatory diagram for description of a method of manufacturing the compound component device according to the first embodiment;

FIG. 9B is an explanatory diagram for the description of the method of manufacturing the compound component device according to the first embodiment; and

FIG. 10 is a sectional view of a modification of the compound component device according to the first embodiment.

### DETAILED DESCRIPTION

Hereinbelow, a compound component device that is an aspect of the present disclosure will be described in detail with reference to embodiments illustrated in the drawings. Incidentally, the drawings may include schematic ones and may lack reflection of actual dimensions or proportions.

In the present disclosure, “contact” means that an intended member is in physical touch with another member with a different member not interposed therebetween (directly) or interposed therebetween (indirectly).

In the present disclosure, “join” means that an intended member is physically jointed to another member with a different member not interposed therebetween (directly) or interposed therebetween (indirectly).

In the present disclosure, “bond” means that an intended member is physically connected to another member with a different member not interposed therebetween (directly) or interposed therebetween (indirectly).

In the present disclosure, “electrically connect” means that an intended member has conductivity to another member with a different member not interposed therebetween (directly) or interposed therebetween (indirectly).

### First Embodiment: Compound Component Device

A compound component device according to a first embodiment is a compound component device including a plurality of laminated first compound component layers housing first electronic components. The first compound component layers each include an electronic component layer, including a first main surface and a second main surface opposed to the first main surface, and a redistribution layer provided on the first main surface. At least two of the plurality of first compound component layers configure an inverted layer for which the first compound component layers are paired and formed so that the second main surfaces face each other. The electronic component layer includes the first electronic component, a first resin sealing portion to seal the first electronic component, a side wall portion that is placed so as to enclose the first electronic component, and electronic component layer piercing vias to pierce the side wall portion and to electrically connect with the redistribution layer, and the first electronic component is directly joined to the redistribution layer.

### Functional Mechanism

The compound component device according to the first embodiment is capable of curbing occurrence of a warpage. Though there is no constraint imposed by a particular theory, a reason for that is inferred as follows.

In the compound component device according to the first embodiment, the plurality of first compound component layers configure the inverted layer for which the first compound component layers are paired and placed so that the second main surfaces of the first compound component layers face each other. Such configuration of the inverted layers by a set of first compound component layers enables separation of the first resin sealing portion into two portions. Thus, internal stresses can be reduced, so that occurrence of a warpage in the entire compound component device can be curbed.

Further, the configuration of the inverted layer by the set of first compound component layers makes the internal stresses which occur in the first compound component layers in the inverted layer prone to have opposite directions and thus makes the internal stresses in the inverted layer prone to be canceled out, so that the occurrence of a warpage in the entire compound component device is curbed.

Accordingly, the compound component device according to the first embodiment is capable of curbing the occurrence of a warpage.

Further, the compound component device according to the first embodiment is superior in rigidity. Though there is no constraint imposed by a particular theory, a reason for that is inferred as follows.

In the compound component device according to the first embodiment, the plurality of first compound component layers configure the inverted layer for which the first compound component layers are paired and placed so that the second main surfaces of the first compound component layers face each other and, further, the electronic component layer includes the side wall portion that is placed so as to enclose the first electronic component. Therefore, there is resistance to occurrence of deformation (dimension change: elongation and contraction, flexure, and torsion, for instance) in response to internal stresses.

Accordingly, the compound component device according to the first embodiment is superior in rigidity.

### Configuration of Compound Component Device

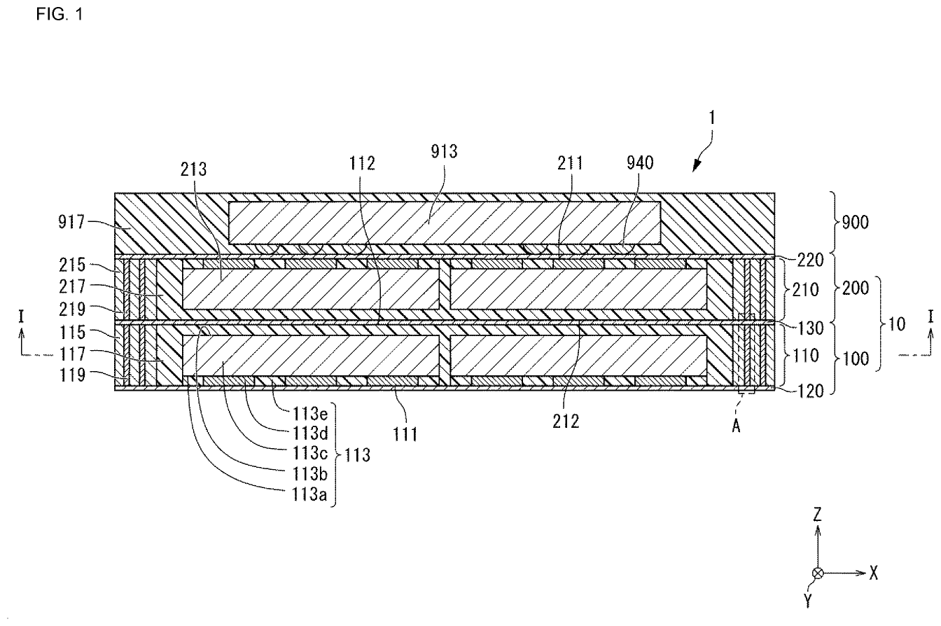

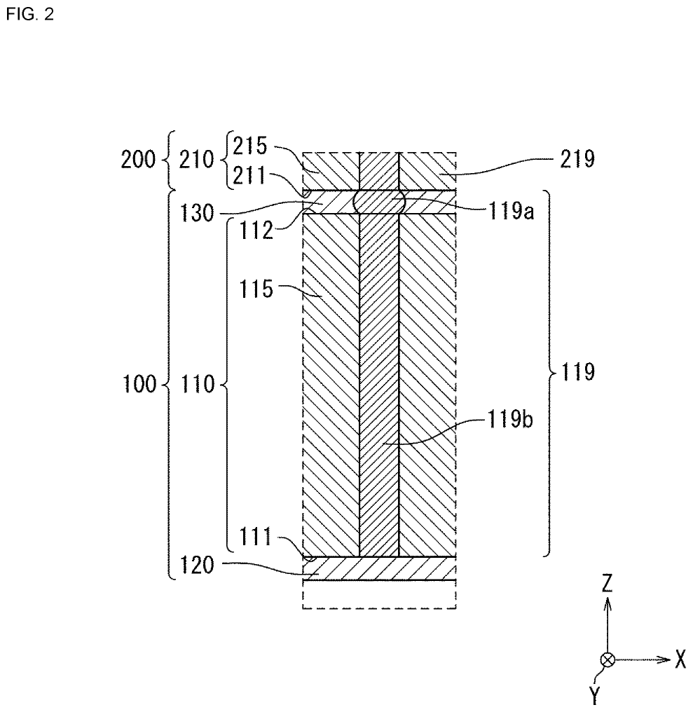

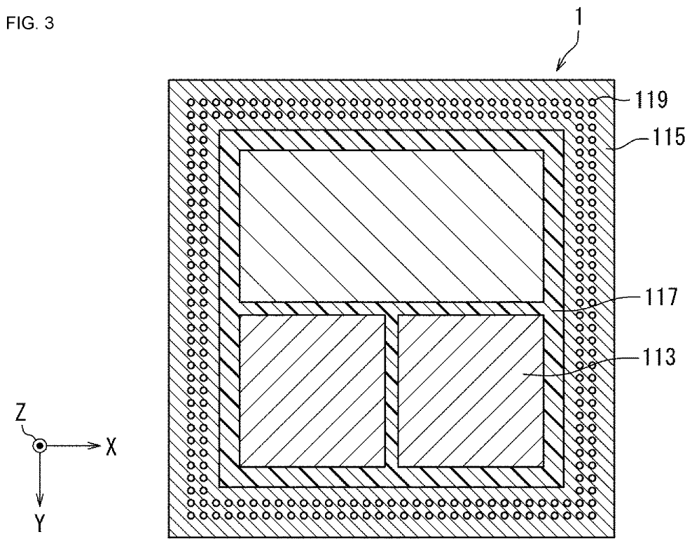

Configurations of the compound component device according to the first embodiment will be described with reference to FIGS. 1, 2, and 3. FIG. 1 is a diagram schematically illustrating a section of the compound component device according to the first embodiment of the present disclosure. FIG. 2 is an enlarged view of a portion A of FIG. 1. FIG. 3 is a sectional view along I-I of FIG. 1.

As illustrated in FIG. 1, a compound component device 1 includes two laminated first compound component layers 100, 200 and further includes one second compound component layer 900. In FIG. 1, directions parallel to thickness of the compound component device 1 are defined as Z directions and a forward Z direction and a reverse Z direction are defined as upper side and lower side, respectively. A direction perpendicular to Z direction in the section of the compound component device 1 illustrated in FIG. 1 is defined as X direction. A direction perpendicular to the section of the compound component device 1 illustrated in FIG. 1 is defined as Y direction.

### First Compound Component Layer, Inverted Layer

The two adjoining first compound component layers 100, 200 configure an inverted layer 10 for which the first compound component layers 100, 200 are paired and placed so that second main surfaces 112, 212 face each other. In the inverted layer 10, the first compound component layer 100 and the first compound component layer 200 relate so as to face each other and thus, even if an internal stress occurs in each of the first compound component layers 100, 200, the internal stresses are prone to have opposite directions, so that the internal stresses in the inverted layer 10 are prone to cancel out each other. As a result, occurrence of a warpage is curbed in the entire compound component device 1.

In terms of further curbing on the occurrence of a warpage in the compound component device 1, the first compound component layer 100 and the first compound component layer 200 in the inverted layer 10 are preferably in symmetry (line symmetry) with each other with respect to a bonding layer 130 corresponding to an interface therebetween. That is because the internal stresses produced in the first compound component layers 100, 200 are prone to have opposite directions, so that the occurrence of a warpage is further curbed, on condition that at least one of configurations (more specifically, placement sites, numbers, types, dimensions, shapes, and the like of electronic component layers 110, 210, redistribution layers 120, 220, first electronic components 113, 213, side wall portions 115, 215, first resin sealing portions 117, 217, electronic component layer piercing vias 119, 219, and the bonding layer 130) of the first compound component layers 100, 200 is in line symmetry relation, for instance.

In terms of further curbing on the occurrence of a warpage in the compound component device 1, at least portions of materials configuring members in the first compound component layer 100 and the first compound component layer 200 in the inverted layer 10 are preferably identical on both sides of the bonding layer 130 that corresponds to the interface therebetween. That is because the internal stresses produced in the first compound component layers 100, 200 are prone to have opposite directions, so that the occurrence of a warpage is further curbed, on condition that the configurations of the first compound component layers 100, 200 are in the line symmetry relation and on condition that at least portions of the materials configuring the members (more specifically, materials configuring the first electronic components 113, 213, the side wall portions 115, 215, the first resin sealing portions 117, 217, the electronic component layer piercing vias 119, 219, and the bonding layer 130) are additionally identical, for instance.

Though the compound component device 1 includes the two first compound component layers 100, 200, the compound component device 1 may include three or more first compound component layers. The configurations of the first compound component layer 200 are substantially identical with those of the first compound component layer 100 in the first embodiment and thus the first compound component layer 100 will be cited as an example and will be described below. Portions that are different, however, will be described separately.

The first compound component layer 100 includes the electronic component layer 110 and the redistribution layer 120 provided on a first main surface 111 of the electronic component layer 110.

### Electronic Component Layer

The electronic component layer 110 includes the first main surface 111 and the second main surface 112 opposed to the first main surface 111. The electronic component layer 110 bonds (joins) to the redistribution layer 120 on the first main surface 111 and bonds to the second main surface 212 of the first compound component layer 200 on the second main surface 112 with the bonding layer 130 interposed therebetween. The electronic component layer 210 includes a first main surface 211 and the second main surface 212 opposed to the first main surface 211. The electronic component layer 210 bonds to the redistribution layer 220 on the first main surface 211 and bonds to the second main surface 112 of the first compound component layer 100 on the second main surface 212 with the bonding layer 130 interposed therebetween. Herein, the redistribution layers 120, 220 are sheets or substrates that are multilayer interconnection layers, for instance, as will be described later and include interconnections (conducting interconnections) and dielectric film including inorganic material (inorganic insulator material), for instance.

The electronic component layer 110 includes the first electronic component 113, the first resin sealing portion 117 to seal the first electronic component 113, the side wall portion 115 that is placed so as to enclose the first electronic component 113, and the electronic component layer piercing vias 119 to pierce the side wall portion 115 and to electrically connect with the redistribution layer 120.

The electronic component layer 110 may include a plurality of first electronic components 113 per layer. On condition that the electronic component layer 110 includes a plurality of first electronic components 113 per layer, the first compound component layer 100 is enabled to function as an electronic substrate by the one layer alone. Accordingly, the compound component device 1 according to the first embodiment can be reduced in height. Further, on condition that the electronic component layer 110 includes a plurality of first electronic components 113 per layer, the plurality of first electronic components 113 may differ (in type).

### —First Electronic Component—

One or more first electronic components 113 may be placed in the electronic component layer 110. The first electronic components 113 are sealed in the electronic component layer 110 with the first resin sealing portion 117. On condition that the plurality of first electronic components 113 exist in the electronic component layer 110, the first electronic components 113 may be identical or may be different. Thicknesses of the first electronic components 113 are 80 to 120 μm, for instance.

The first electronic components 113 are directly joined to the redistribution layer 120. In other words, all the first electronic components 113 in the electronic component layer 110 are placed in the electronic component layer 110 so that first surfaces 113a are positioned on a side of the redistribution layer 120 with respect to respective second surfaces 113b. Ditto for all the first electronic components 213 in the electronic component layer 210. In the compound component device 1, such simple interconnections enable lamination of not only two compound component layers but three or more compound component layers. That is, the compound component device according to the present disclosure facilitates multilayer configuration of the first compound component layers, thus facilitates adjustment of number of the layers in accordance with an application, and heightens degree of freedom of design.

The first electronic components 113 are electronic components in which one or more elements are integrated in a substance similar to a substance that configures the side wall portion 115, for instance. The first electronic components 113 are electronic components that are smaller in dimension (smaller electronic components) compared with a second electronic component 913 that will be described later. The first electronic components 113 are electronic components that are comparatively easy of reduction in dimensions and height because of a structure thereof and/or that generally generate comparatively large amounts of heat. Such first electronic components 113 are active components (more specifically, CPU, GPU, LSI, and the like) and passive components (more specifically, capacitors (further specifically, low-capacitance capacitors or the like), resistors, SAW, inductors, and the like), for instance.

The first electronic components 113 each include an electronic component main body portion 113c having the first surface 113a perpendicular to a thickness direction and the second surface 113b opposed to the first surface 113a and a plurality of component electrodes 113d placed on the first surface 113a and electrically connected to the redistribution layer 120. The first electronic components 113 each further include insulating portions 113e placed between the plurality of component electrodes 113d.

The electronic component main body portion 113c includes ceramic or semiconductor material (more specifically, silicon or the like), for instance.

The component electrodes 113d are directly joined to the redistribution layer 120 and are electrically connected to the redistribution layer 120. The component electrodes 113d have Cu, Ni, Sn, Al, and an alloy including those, for instance, as conductive material. Thicknesses of the component electrodes 113d are 1 to 30 μm, for instance, and 5 μm or less, preferably. The thicknesses of the component electrodes 113d can be made as thin as 1 to 5 μm. The thicknesses of the component electrodes 113d can be ¼ to ⅙ times a thickness of the electronic component main body portion 113c, for instance.

The insulating portions 113e function as a layer to make electrical insulation between the component electrodes 113d. Thicknesses of the insulating portions 113e are 1 to 30 μm, for instance, and 5 μm or less, preferably. The thicknesses of the insulating portions 113e can be made as thin as 1 to 5 μm. The thicknesses of the insulating portions 113e can be ¼ to ⅙ times the thickness of the electronic component main body portion 113c, for instance. The insulating portions 113e may be as thick as the component electrodes 113d and, in that case, surfaces of the insulating portions 113e are made flush with surfaces of the component electrodes 113d.

### —Resin Sealing Portion—

The first resin sealing portion 117 seals the first electronic components 113.

The first resin sealing portion 117 includes resin (epoxy resin, for instance) and is capable of integrating the first electronic components 113 with the resin. The first electronic components 113 can be integrated with the resin and thus two or more first electronic components 113 can be placed in the electronic component layer 110 even if the two or more first electronic components 113 differ in dimensions and shape. Thus, design with high degree of freedom is enabled so that two or more first electronic components 113 can be combined in accordance with an application. For instance, the compound component device 1 is capable of housing different types of first electronic components 113.

As epoxy resin to configure the first resin sealing portion 117, thermosetting resin containing a recurring unit derived from benzocyclobutene (BCB) (more specifically, 1,3-divinyl-1,1,3,3-tetramethyldisiloxane-bis-benzocyclobutene (DVS-bis-BCB) or the like) can be cited, for instance. As commercially available epoxy resin, “CYCLOTENE” manufactured by The Dow Chemical Company can be cited, for instance.

In the electronic component layers 110, 210, resins that configure the first resin sealing portions 117, 217 may be identical or may be different. Herein, being different encompasses being partially different. In a second embodiment, for instance, there are three electronic component layers 110, 210, 310. The above-described resins that are different in type encompass an aspect in which the resins that configure the first resin sealing portions 117, 217 are different from a resin that configures a first resin sealing portion 317 and an aspect in which the resin that configures the first resin sealing portion 117, the resin that configures the first resin sealing portion 217, and the resin that configures the first resin sealing portion 317 are different.

On condition that the resins configuring the first resin sealing portions 117, 217 are different in type, the first resin sealing portions 117, 217 may be provided with respective different functions (more specifically, high thermal conductivity (high heat radiation), thermal expansivity, low hygroscopicity, and the like) with the resins configuring the compound component layers made different, for instance. For instance, the first resin sealing portion 117 may be provided with the high thermal conductivity and the first resin sealing portion 217 may be provided with the low hygroscopicity. As commercially available resins with the high thermal conductivity, “CV8511” manufactured by Panasonic Corporation and “G780” manufactured by Sumitomo Bakelite Co., Ltd. can be cited, for instance.

Incidentally, “thermal expansivity of resin” mentioned above refers to a property through which a volume of resin expands with provision of heat for the resin, herein. As a physical property indicating the thermal expansivity, coefficient of linear expansion can be cited, for instance.

In terms of increase in thermal conductivity (heat radiation) of the first resin sealing portion 117, the first resin sealing portion 117 may further include filler. As a material of the filler to increase the thermal conductivity, inorganic material can be cited, for instance. Alumina (Al₂O₃), silicon oxide (SiO₂), silicon nitride (Si₃N₄), boron nitride (BN), and aluminum nitride (AlN) can be cited as such inorganic materials, for instance, and aluminum nitride is desirable thereamong in terms of further increase in thermal conductivity of the first compound component layer 100. As a commercially available resin including inorganic filler, “R4507” (inorganic filler: SiO₂) manufactured by Nagase ChemteX Corporation can be cited, for instance.

### —Side Wall Portion—

As illustrated in FIG. 2 in addition to FIG. 1, the side wall portion 115 is placed so as to surround the first electronic components 113 and, more specifically, is placed around the electronic component layer 110 so as to surround entirety of the one or more first electronic components 113. The electronic component layer piercing vias 119 pierce an inner portion of the side wall portion 115. The side wall portion 115 has a substantially rectangular shape in a sectional (ZX section) view, has a top surface connected to the first compound component layer 200 with the bonding layer 130 interposed therebetween, and has a bottom surface bonded to the redistribution layer 120. A thickness of the side wall portion 115 is 50 to 150 μm, for instance.

The side wall portion 115 preferably includes a material (inorganic material, for instance) that has a smaller coefficient of linear expansion than the material (resin) of the first resin sealing portion 117 has. On condition that the side wall portion 115 includes a material that has a smaller coefficient of linear expansion than the material of the first resin sealing portion 117 has, an amount of resin to contract in the first resin sealing portion 117 can be reduced by an existing volume of the side wall portion 115 and thus the compound component device 1 is capable of curbing occurrence of a warpage.

More preferably, the side wall portion 115 is substantially made of silicon (Si) among the above inorganic materials. Herein, “substantially made of” means that an object (the side wall portion 115 in the above) includes a particular material (silicon in the above) at a content rate of 95% or more by mass, 97% or more by mass, 99% or more by mass, or 100% by mass. On condition that the side wall portion 115 is substantially made of silicon, silicon, which excels in workability, may form a worked surface that accurately reflects design. Thus, miniaturization of interconnection widths and decrease in connection resistance of the interconnections are enabled for the electronic component layer piercing vias 119 that pierce the side wall portion 115. On condition that the side wall portion 115 is substantially made of silicon, accordingly, the compound component device 1 according to the first embodiment has high reliability.

### —Electronic Component Layer Piercing Via—

The electronic component layer piercing vias 119 are provided so as to be substantially parallel to a laminating direction (Z direction) for the first compound component layers 100, 200. More specifically, the electronic component layer piercing vias 119 pierce the electronic component layer 110 in Z direction and further pierce the bonding layer 130. As illustrated in FIG. 2, the electronic component layer piercing vias 119 include conducting vias 119a piercing the bonding layer 130 and side wall portion piercing vias 119b piercing the side wall portion 115. The conducting vias 119a make electrical connections between the electronic component layer piercing vias 119 and the electronic component layer piercing vias 219 of the first compound component layers 200. In a plane perpendicular to a thickness direction of the compound component device 1, a cross-sectional area (cross-sectional area in XY plane) of the conducting via 119a is larger than a cross-sectional area of the side wall portion piercing via 119b. Thus, the electronic component layer piercing vias 119 have satisfactory electrical connections with the electronic component layer piercing vias 219 and connection resistance between the first compound component layers 100, 200 is decreased. Accordingly, reliability of the compound component device 1 according to the first embodiment is further increased.

Preferably, the electronic component layer piercing vias 119 are substantially made of copper. On condition that the electronic component layer piercing vias 119 are substantially made of copper, electric resistance of the interconnections is decreased because copper is a satisfactory electrical conducting material.

With reference to FIG. 3 in addition to FIG. 1, arrangement of the electronic component layer piercing vias 119 will be described. FIG. 3 is a sectional view along I-I of FIG. 1. In XY section (that is, a section perpendicular to the laminating direction for the first compound component layers 100, 200) of FIG. 3, the plurality of electronic component layer piercing vias 119 exist and are provided so as to surround the first electronic components 113 and the first resin sealing portion 117 and so as to be placed with alignment.

Herein, “place(ment) with alignment” refers to placement with arrangement at equal interval distances (which may be referred to as “distance L₁” below) on orthogonal straight lines in plan view. On condition that a plurality of straight lines exist on one side in the orthogonal straight lines, the plurality of parallel straight lines adjoin spaced apart by the distance L₁.

With reference to FIG. 3 as an example, “placement with alignment” will be described in detail. As illustrated in FIG. 3, the plurality of electronic component layer piercing vias 119 are provided to be placed with alignment so as to surround the first resin sealing portion 117. On a top side on a sheet of FIG. 3, a plurality of electronic component layer piercing vias 119 are arranged at the equal interval distances L₁ on two straight lines parallel to X direction. The two straight lines adjoin spaced apart by the same distance as the distance L₁ between the adjoining electronic component layer piercing vias 119. Ditto for a plurality of electronic component layer piercing vias 119 on a bottom side on the sheet of FIG. 3.

On a left side on the sheet of FIG. 3, meanwhile, a plurality of electronic component layer piercing vias 119 are arranged at the equal interval distances L₁ on two straight lines parallel to Y direction (orthogonal to X direction). The two straight lines adjoin spaced apart by the same distance as the distance L₁ between the adjoining electronic component layer piercing vias 119. Ditto for a plurality of electronic component layer piercing vias 119 on a right side on the sheet of FIG. 3.

### Redistribution layer

The redistribution layer 120 is formed on the first main surface 111 of the electronic component layer 110. The redistribution layer 120 is electrically connected to the component electrodes 113d of the first electronic components 113 and to the electronic component layer piercing vias 119. The redistribution layer 120 is directly joined to (the component electrodes 113d of) the first electronic components 113 and thus lengths of via interconnections between the redistribution layer 120 and the component electrodes 113d can be decreased. Accordingly, the compound component device 1 according to the first embodiment can be reduced in dimensions and height and electric resistance of the via interconnections can be decreased.

The redistribution layer 120 is a multilayer interconnection layer. The redistribution layer 120 includes the interconnections (conducting interconnections), the dielectric film substantially made of insulator material, and conductive vias to electrically connect the interconnections between different layers in the redistribution layer 120.

The interconnections and the conductive vias include conductive material. Examples of the conductive material are Cu, Ag, Au, and an alloy including those and Cu is desirable among those. The redistribution layer 120 may include a plurality of layers and includes two or more layers of the interconnections and one or more layers of the dielectric film, for instance. One layer of the interconnections and one layer of the dielectric film that configure the redistribution layer 120 have a thickness of 1.5 to 5.0 μm, for instance. In this configuration, a thickness of the redistribution layer 120 has a value (unit: μm) of the thickness (1.5 to 5.0 μm) of the one layer multiplied by a total number of layers in the redistribution layer 120.

The dielectric film includes inorganic insulator material or organic insulator material as insulator material, for instance, and, preferably, is substantially made of the inorganic insulator material or the organic insulator material. As the inorganic insulator material, silicon oxide (SiO₂) and silicon nitride (SiN, Si₃N₄) can be cited, for instance. As the organic insulator material, epoxy resin, silicone resin, polyester, polypropylene, polyimide, acrylonitrile-butadiene-styrene (ABS) resin, acrylonitrile-styrene (AS) resin, methacrylic resin, polyamide, fluorine resin, liquid crystal polymer, polybutylene terephthalate, and polycarbonate can be cited, for instance.

On condition that the redistribution layer 120 includes the dielectric film (which may be referred to as “inorganic dielectric film” below) substantially made of the inorganic material (inorganic insulator material, for instance), widths of the interconnections (interconnection widths) in the redistribution layer 120 can be miniaturized and the compound component device 1 according to the first embodiment can be reduced in dimensions, compared with the dielectric film substantially made of the organic material (organic insulator material, for instance). That is because the inorganic dielectric film, having extreme smaller film surface roughness than the organic dielectric film, increases positional accuracy of a focus in a lithography step in interconnection formation, compared with the organic dielectric film. More specifically, focusing on nanometer order can be carried out for the inorganic dielectric film, while focusing on micrometer order can be carried out for the organic dielectric film. The interconnection widths of the interconnections in the redistribution layer 120 substantially made of the inorganic dielectric film can be about 1/10 of those of the interconnections in the redistribution layer 120 including the dielectric film substantially made of the organic insulator material. Thus, the compound component device 1 can be reduced in dimensions and height. Line and space (L/S) of the redistribution layer 120 including the dielectric film substantially made of the inorganic insulator material is 1 μm/1 μm, for instance.

A thickness of the inorganic dielectric film is 0.1 to 2 μm, for instance. The inorganic dielectric film may be multicomponent film containing two or more types of components. The multicomponent film may be multilayer film in which a plurality of layers are formed of respective components. A layer structure of the multilayer film is SiO₂ (0.25 μm thick)/Si₃N₄ (0.1 μm thick)/SiO₂ (0.25 μm thick)/Si₃N₄ (0.1 μm thick) in order of mention from a side of the electronic component layer 110, for instance.

On condition that the dielectric film is substantially made of the organic insulator material, the dielectric film can be formed with reduction in costs. That is because the dielectric film substantially made of the organic insulator material can be manufactured without use of such large-scale facilities as plasma-enhanced chemical vapor deposition (PECVD) device, compared with the dielectric film substantially made of the inorganic insulator material.

Line and space (L/S) of the redistribution layer 120 substantially made of the organic dielectric film is 10 μm/10 μm, for instance. A thickness of the dielectric film is 1 to 20 μm, for instance.

### Bonding Layer

The bonding layer 130 forms a bond between the first compound component layers 100, 200. Material of the bonding layer 130 is thermosetting resin, for instance.

### Second Compound Component Layer

The compound component device 1 may further include the second compound component layer 900 as an outermost layer. The second compound component layer 900 is placed on the first compound component layer 200 that is an uppermost layer of the laminated first compound component layers 100, 200. The second compound component layer 900 includes the second electronic component 913 and a second resin sealing portion 917 to seal the second electronic component 913 and includes no side wall portion.

Herein, “outermost layer” refers to a layer having a main surface exposed on an object. In FIG. 1, the second compound component layer 900 has a main surface exposed on the compound component device 1. Therefore, the second compound component layer 900 is the outermost layer. Incidentally, though the second compound component layer 900 is bonded to the first compound component layer 200, the second compound component layer 900 may be bonded to the first compound component layer 100, instead.

On condition that the compound component device 1 further includes the second compound component layer 900 as the outermost layer, occurrence of burrs (more specifically, cracks, breakage, chipping, and the like) is curbed in a dicing step of a method of manufacturing the compound component device 1 that will be described later. Accordingly, such a configuration of the compound component device 1 according to the first embodiment accurately reflects design and has high reliability.

The occurrence of the burrs is curbed by reasons as follows. Without inclusion of the second compound component layer 900, a mother integrated body of the compound component device 1 is cut along the side wall portion 215 of the first compound component layer 200 placed as the outermost layer. The side wall portion 215 is substantially made of an inorganic substance (Si, for instance) under normal conditions and, accordingly, there is limitation on reduction in the occurrence of the burrs in cutting along the side wall portion 215, even if cutting conditions in the dicing step are adjusted. With the inclusion of the second compound component layer 900, by contrast, the mother integrated body of the compound component device 1 is cut at the second resin sealing portion 917 of the second compound component layer 900 placed as the outermost layer. The second resin sealing portion 917 is substantially made of resin under normal conditions and, accordingly, the occurrence of the burrs in cutting at the second resin sealing portion 917 can be reduced by adjustment of the cutting conditions in the dicing step.

The second electronic component 913 is electrically connected to the redistribution layer 220 of the first compound component layer 200 with solder 940 interposed therebetween. The second electronic component 913 is an electronic component that is larger in dimensions (larger electronic component) compared with the first electronic components 113, 213. The second electronic component 913 is an electronic component that is comparatively difficult of reduction in dimensions and height because of a structure thereof and/or that generally generates a comparatively large amount of heat. An electronic component that is comparatively difficult of reduction in dimensions and height because of a structure thereof is a multilayer ceramic capacitor (MLCC) or the like, for instance.

Electronic components that generally generate comparatively large amounts of heat are inductor (more specifically, power inductor or the like), power IC, and the like, for instance.

### Method of Manufacturing Compound Component Device

A method of manufacturing the compound component device 1 according to the first embodiment includes an electronic component bonding step of bonding the first electronic component onto a silicon base layer (Si base layer) so that component electrodes of the first electronic component come into contact with a bottom surface portion of the silicon base layer having a grid-like side wall portion and the bottom surface portion, with an electronic component bonding layer interposed therebetween; an electronic component sealing step of forming a resin sealing portion by sealing of the first electronic component with resin; and an electronic component layer precursor producing step of producing an electronic component layer precursor by removal of the silicon base layer and the electronic component bonding layer such that entirety of surfaces of the component electrodes is exposed. The method also includes an electronic component layer precursor bonding step of producing a pair of electronic component layer precursors by bonding of the two electronic component layer precursors such that main surfaces of the two electronic component layer precursors on which the component electrodes are not exposed face each other; an inverted layer precursor producing step of producing an inverted layer precursor by formation of electronic component layer piercing vias that pierce the side wall portions of the pair of electronic component layer precursors and a redistribution layer on one main surface of the pair of electronic component layer precursors on which the component electrodes are exposed; and an inverted layer producing step of forming an inverted layer by formation of a redistribution layer on the other main surface of the inverted layer precursor that is located on a side opposed to the one main surface. The method further includes a laminating step of laminating the pair of electronic component layer precursors produced separately and one of the electronic component layer precursors produced separately on the redistribution layer of the inverted layer precursor; and an interconnection forming step of forming electronic component layer piercing vias and a redistribution layer in or on the laminated pair of electronic component layer precursors and the laminated one of the electronic component layer precursors. A step in which the laminating step and the interconnection forming step are combined is carried out zero or more times.

The method of manufacturing the compound component device 1 according to the first embodiment may further include an insulating portion forming step of forming insulating portions between component electrodes of an electronic component; a silicon base layer preparing step of preparing a silicon base layer having a grid-like side wall portion and a bottom surface portion; a resin sealing portion thinning step of thinning the first resin sealing portion; a second compound component layer forming step of forming the second compound component layer; and a dicing step of individuating by dicing.

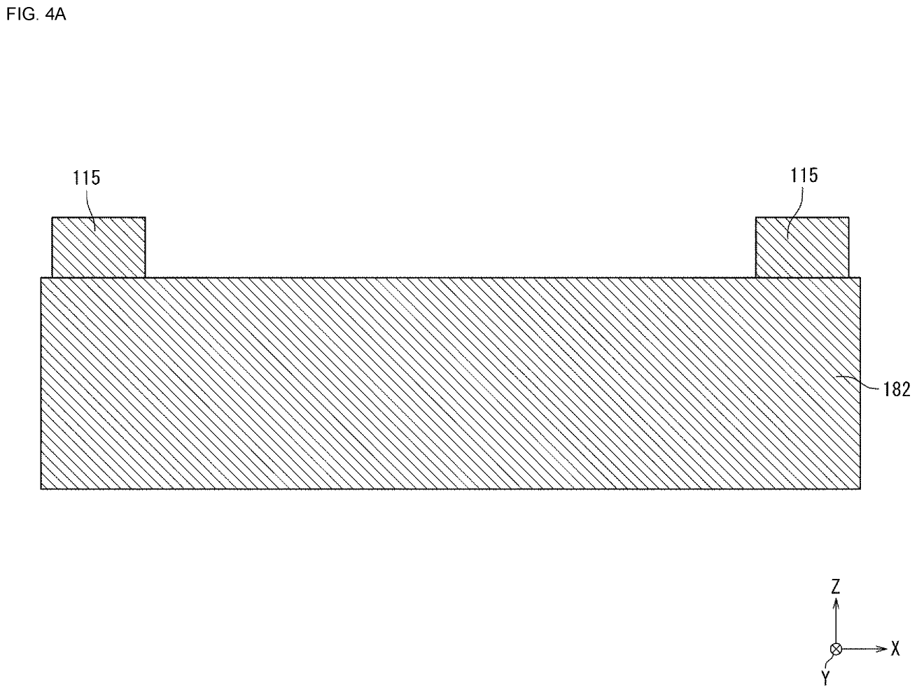

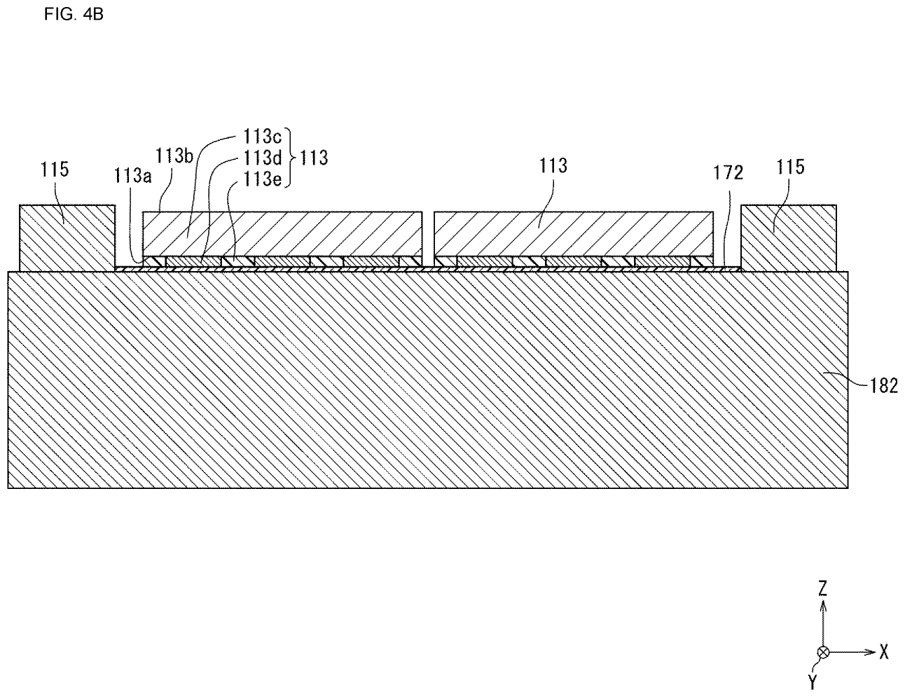

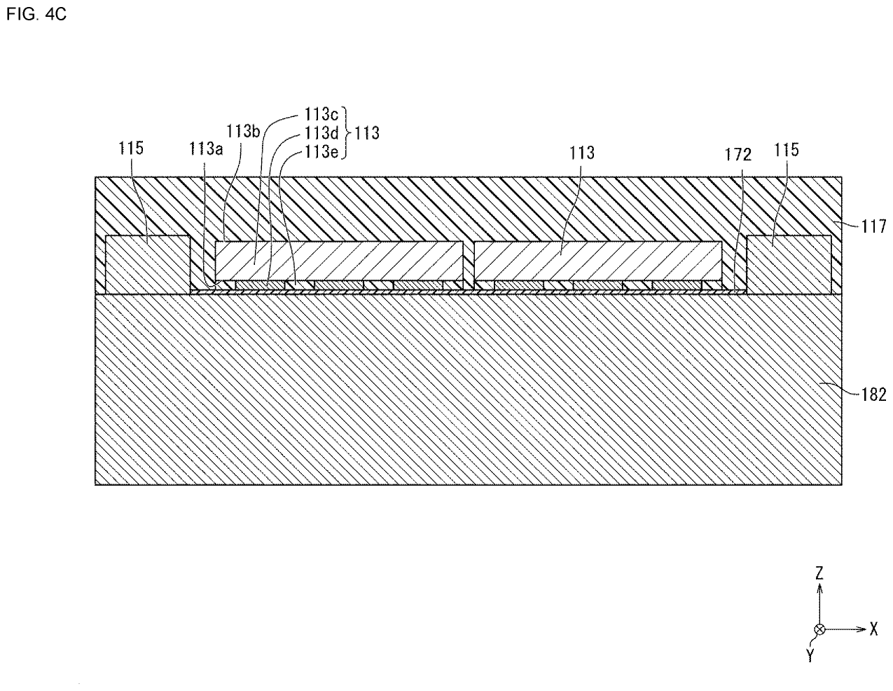

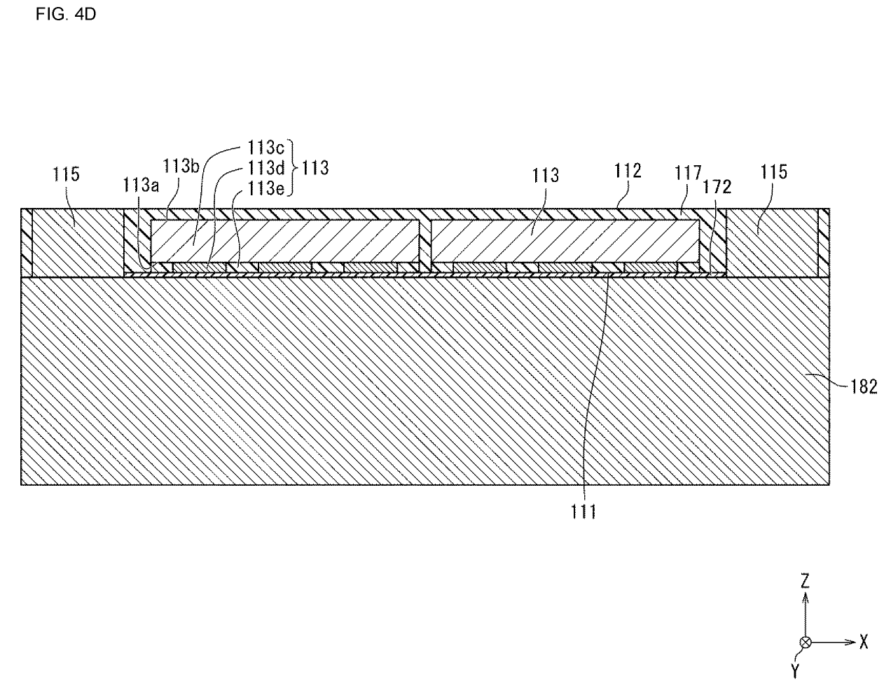

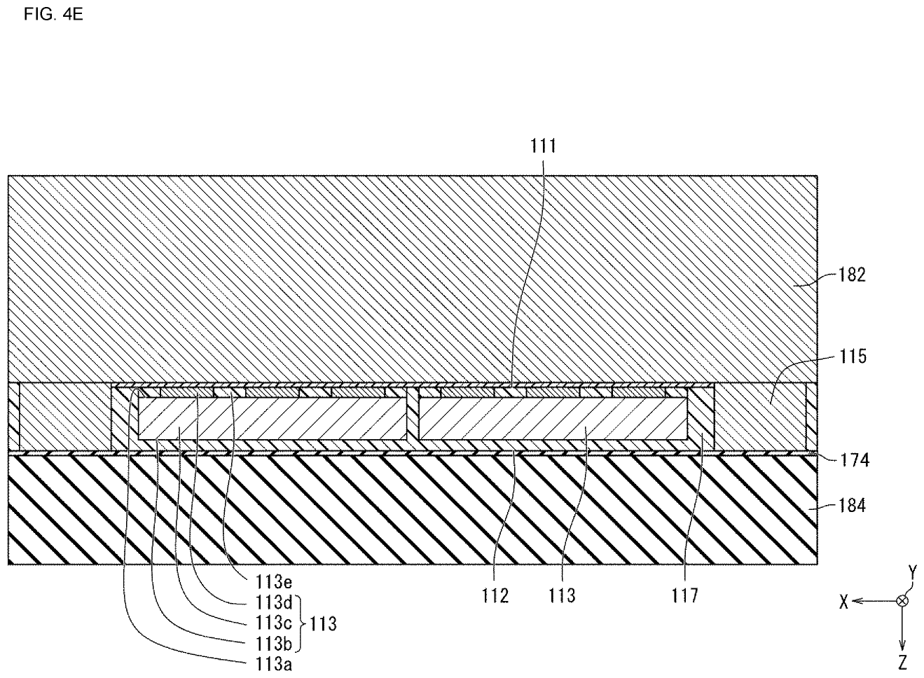

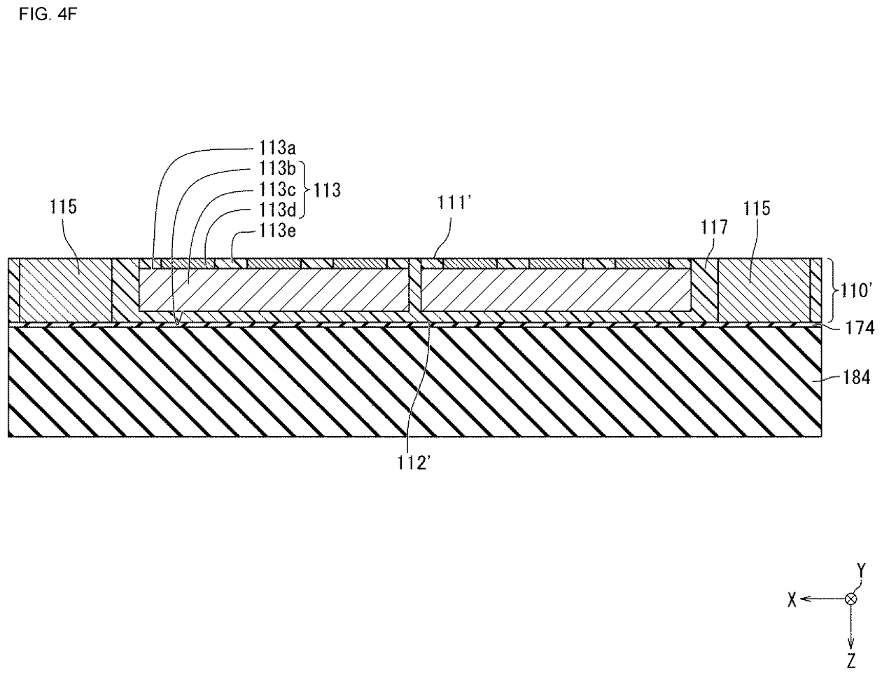

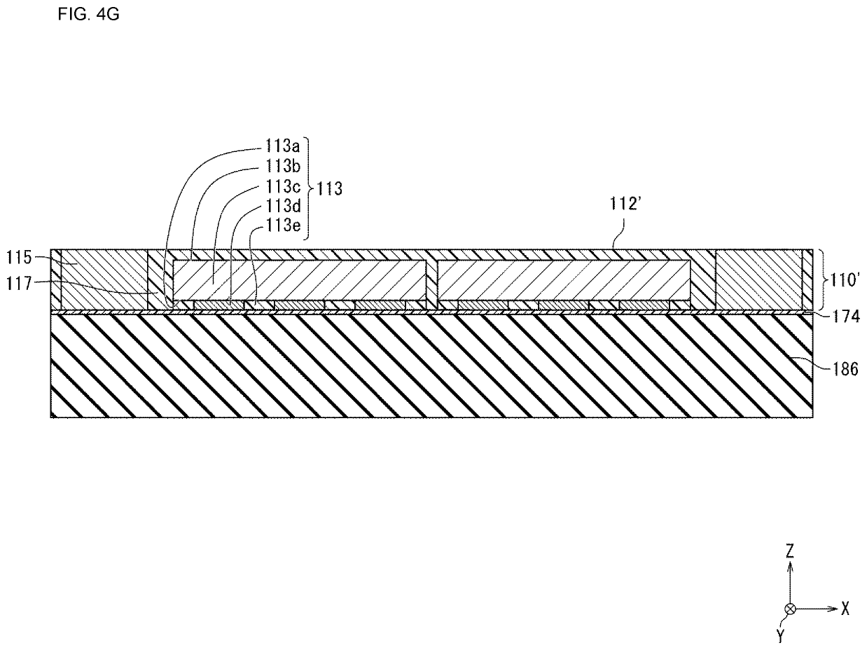

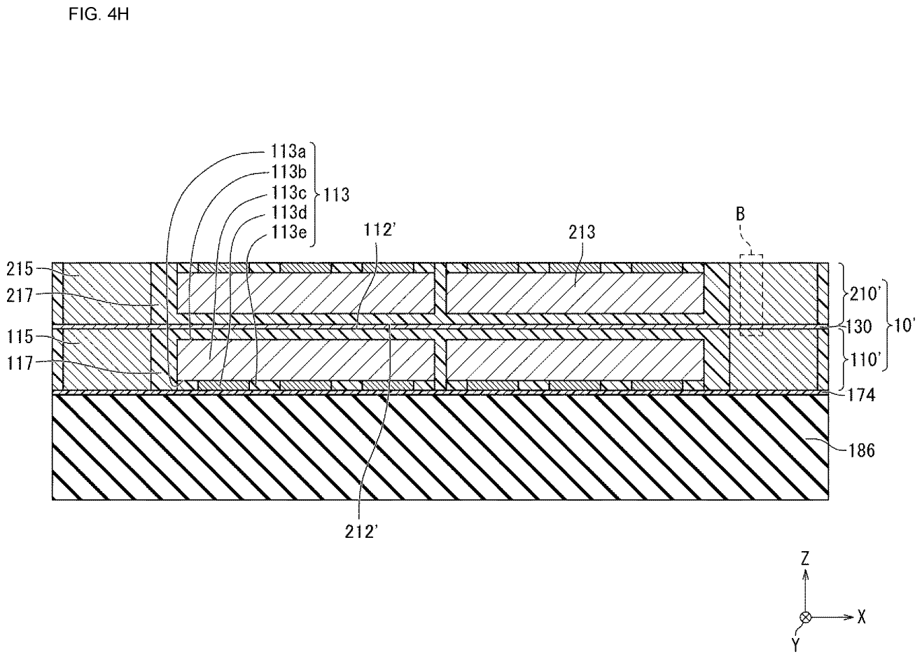

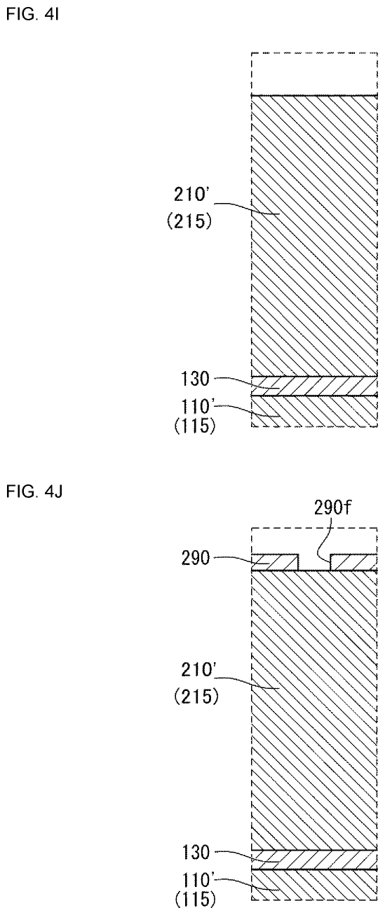

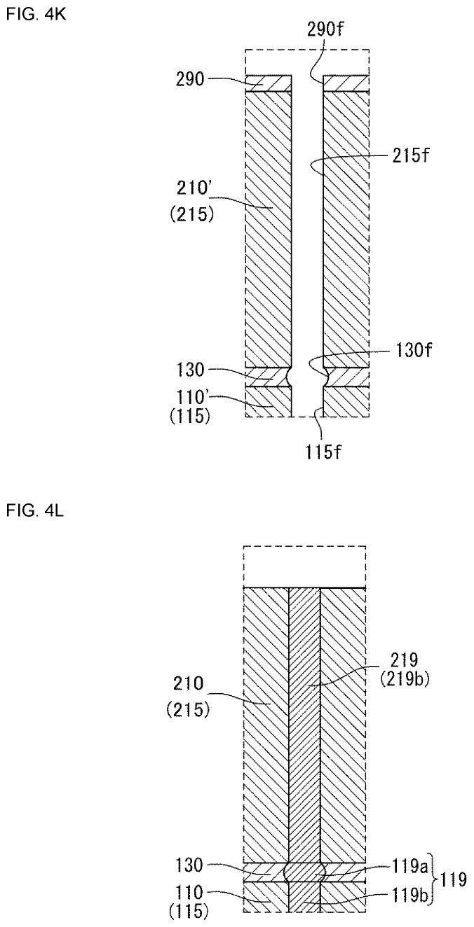

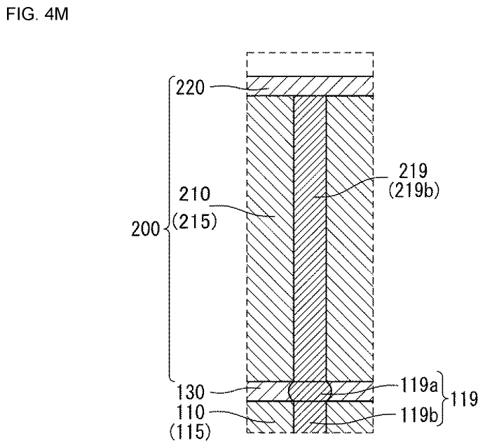

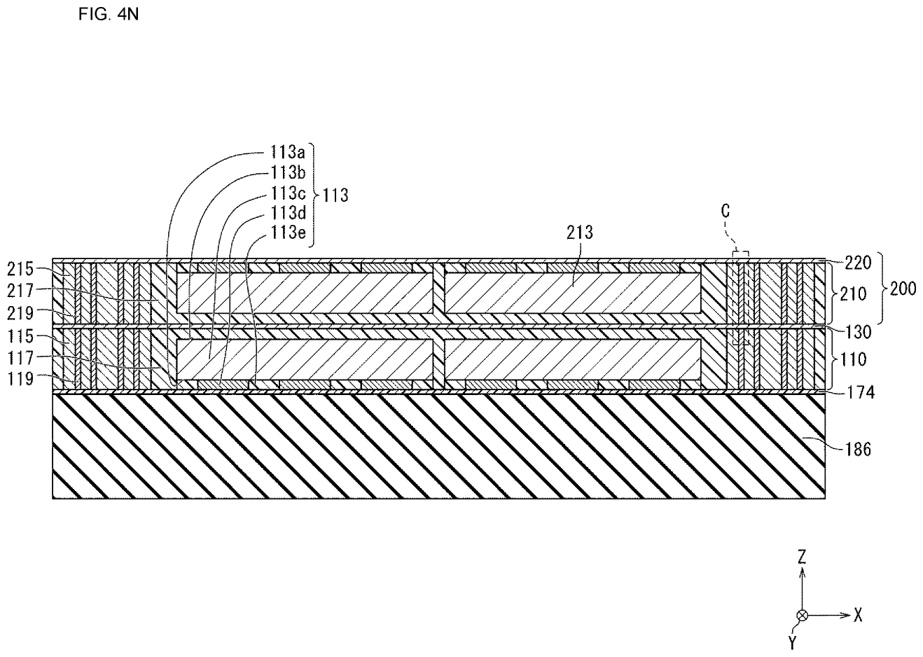

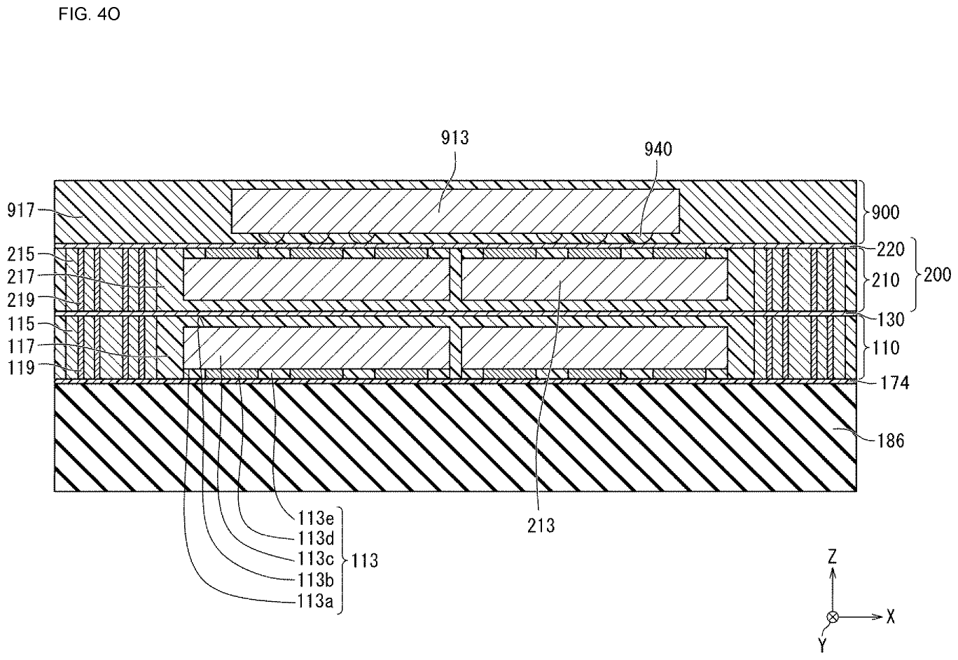

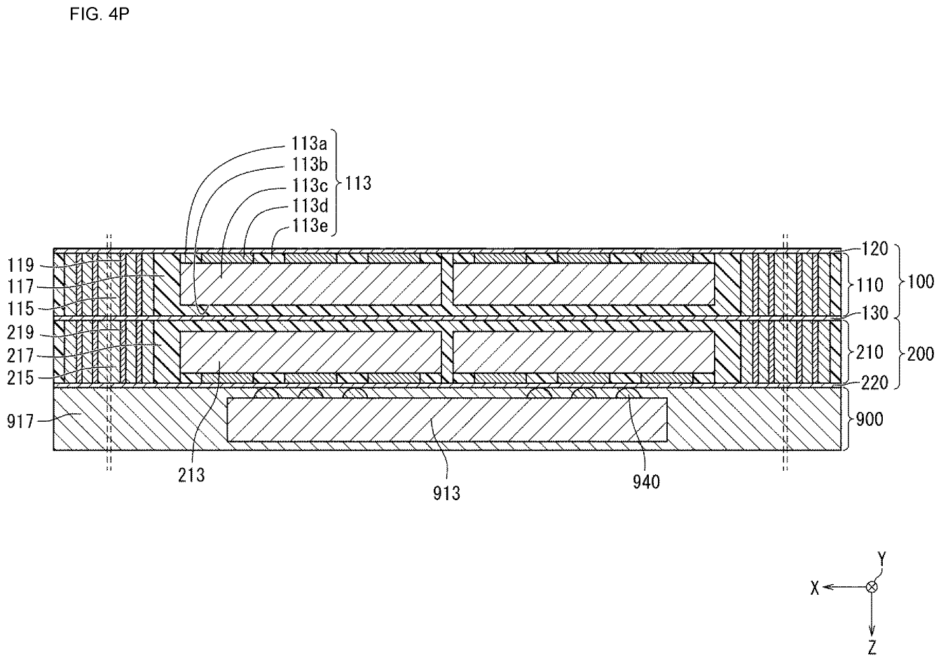

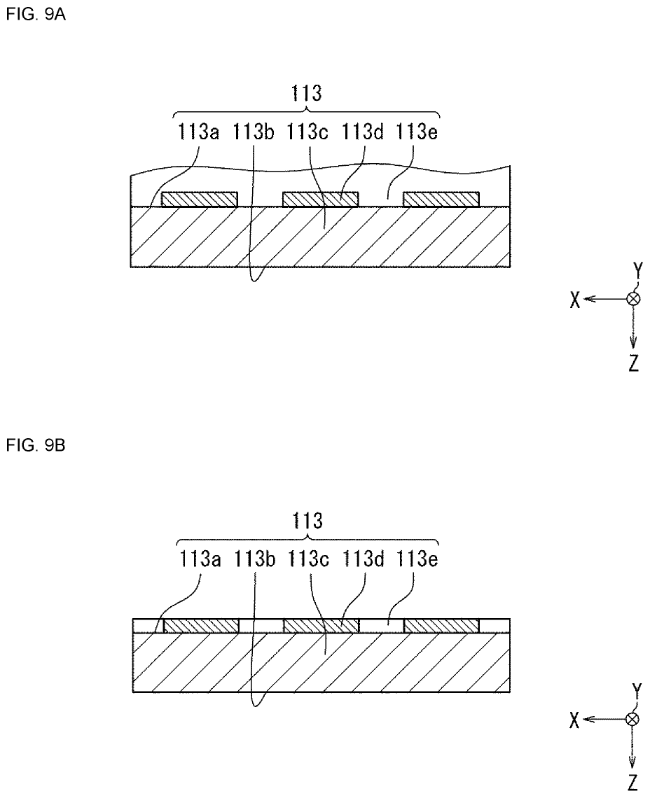

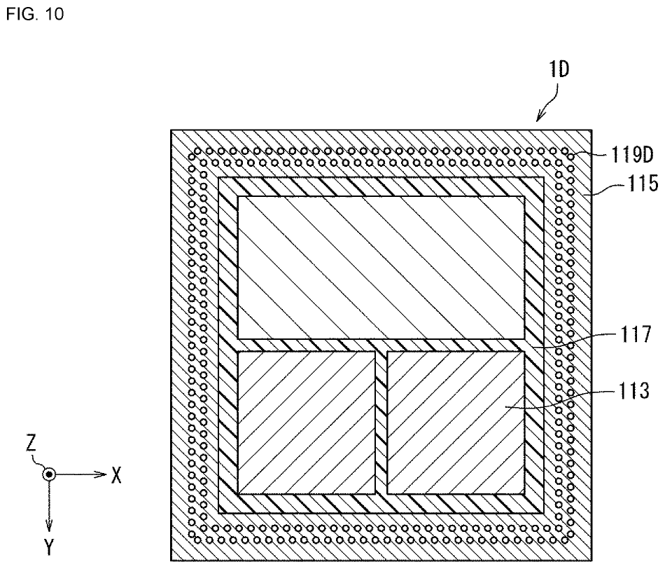

Specifically, an example of the method of manufacturing the compound component device 1 will be described with reference to FIGS. 9A and 9B and FIGS. 4A to 4P. FIGS. 9A and 9B and FIGS. 4A to 4P are diagrams for description of the method of manufacturing the compound component device 1. The method of manufacturing the compound component device 1 according to the first embodiment includes the insulating portion forming step, the silicon base layer preparing step, the electronic component bonding step, the electronic component sealing step, the resin sealing portion thinning step, the electronic component layer precursor producing step, the electronic component layer precursor bonding step, the inverted layer precursor producing step, the second compound component layer forming step, the inverted layer producing step, and the dicing step. In this example, incidentally, the combination of the laminating step and the interconnection forming step is carried out zero times.

In the manufacturing method, the mother integrated body in which the compound component devices 1 are integrated is produced by the silicon base layer preparing step to the inverted layer producing step. FIGS. 4A to 4H and FIGS. 4N to 4P illustrate a site in the mother integrated body to be produced that corresponds to one compound component device.

### Insulating Portion Forming Step

In the insulating portion forming step, as illustrated in FIGS. 9A and 9B, the insulating portions 113e are formed between the component electrodes 113d of the first electronic component 113. Specifically, coating film is formed so as to cover the component electrodes 113d of the first electronic component 113 and planarization processing is carried out, so that the insulating portions 113e are formed between the component electrodes 113d of the first electronic component 113. As illustrated in FIG. 9A, the coating film is formed by coating with solution containing resin and solvent with use of a spin coat method. Herein, a lowest site on the coating film is made higher than a highest site on the component electrodes 113d. That is, the coating film is formed so that all of the plurality of component electrodes 113d may be completely buried in the coating film. The insulating portions 113e are formed by drying of a coating film. Preferably, the insulating portions 113e in a state preceding the following planarization processing completely cover the component electrodes 113d.

In the planarization processing, as illustrated in FIG. 9B, surfaces of the component electrodes 113d and the insulating portions 113e are planarized by being ground with use of a surface planer and a grinder, for instance, so that the insulating portions 113e are formed between the component electrodes 113d. Thus, top surfaces of the component electrodes 113d are exposed and the top surfaces of the component electrodes 113d and of the insulating portions 113e are made flush with one another.

### Silicon Base Layer Preparing Step

In the silicon base layer preparing step, as illustrated in FIG. 4A, a silicon base layer 182 having the grid-like side wall portion 115 and the bottom surface portion is prepared. Specifically, the silicon base layer 182 having the grid-like side wall portion 115 and the bottom surface portion includes the bottom surface portion that is rectangular in plan view and the side wall portion 115 that is placed like grids so as to surround the rectangular bottom surface portion. One or more first electronic components 113 are bonded into recessed portions (or depressions or cavities) surrounded by the bottom surface portion and the side wall portion 115 in the electronic component bonding step that will be described later.

A shape of the silicon base layer 182 may be cylindrical as seen looking down in plan view, whereas there is no limitation thereto. On condition that the shape of the silicon base layer 182 is cylindrical, a thickness of the silicon base layer 182 is 775 μm (diameter of Si wafer is φ 300 mm), 725 μm (φ 200 mm), 675 μm (φ 150 mm), and 525 μm (φ 100 mm), for instance. Incidentally, the silicon base layer preparing step may be carried out prior to the insulating portion forming step. Both the silicon base layer 182 and the side wall portion 115 are substantially made of Si.

### Electronic Component Bonding Step

In the electronic component bonding step, the first electronic components 113 are bonded onto the silicon base layer 182 so that the plurality of component electrodes 113d of the first electronic components 113 come into contact with the bottom surface portion of the silicon base layer 182 having the grid-like side wall portion 115 and the bottom surface portion, with an electronic component bonding layer 172 interposed therebetween. Specifically, in the electronic component bonding step as illustrated in FIG. 4B, the one or more first electronic components 113 are placed (installed) on (the bottom surface portion of) the silicon base layer 182 so that the component electrodes 113d and the insulating portions 113e come into contact with (the bottom surface portion of) the silicon base layer 182 with the electronic component bonding layer 172 (strictly, coating film of adhesive) interposed therebetween. Subsequently, the electronic component bonding layer 172 is formed by hardening of the coating film of adhesive. Thus, the first electronic components 113 are bonded onto the silicon base layer 182.

A method of coating with the coating film is spin coating, for instance. The coating is preferably carried out with control such that a thickness of the coating film is within the range from the thickness of the component electrodes 113d of the first electronic components 113 to 10 μm. The adhesive is thermosetting resin, for instance. Such a thermosetting resin is a thermosetting resin containing a recurring unit derived from benzocyclobutene (BCB), for instance, and can be obtained by polymerization of 1,3-divinyl-1,1,3,3-tetramethyldisiloxane-bis-benzocyclobutene (DVS-bis-BCB), for instance. A commercialized product is “CYCLOTENE” manufactured by The Dow Chemical Company, for instance.

The first electronic components 113 are placed on the coating film with use of a device including a vacuum chamber. More particularly, an electronic component integrated wafer (wafer in which the plurality of first electronic components 113 are integrated) is stuck on the silicon base layer 182 (the silicon base layer 182 including the side wall portion 115). Pressures are applied in two-way directions along the laminating direction for the first electronic components 113 and heating is carried out. Specifically, the silicon base layer 182 is set on a lower stage in the vacuum chamber of the device. The component electrodes 113d of the first electronic components 113 are directed so as to face the coating film and vacuum suction (or decompression suction) of the first electronic components 113 is exerted on an upper stage in the vacuum chamber. A cognitive mark of the silicon base layer 182 is used for positioning between the silicon base layer 182 and the electronic component integrated wafer, for instance. The one or more first electronic components 113 are placed on a side of the coating film on the silicon base layer 182. Pressures are applied in two-way directions along directions in which the upper and lower stages face each other and heating is carried out.

The electronic component integrated wafer is bonded onto the silicon base layer 182 so that the component electrodes 113d and the insulating portions 113e face the silicon base layer 182 with the electronic component bonding layer 172 interposed therebetween.

### Electronic Component Sealing Step

In the electronic component sealing step, the first resin sealing portion 117 is formed by sealing of the first electronic components 113 with resin. In the electronic component sealing step as illustrated in FIG. 4C, specifically, the silicon base layer 182 on which the first electronic components 113 are installed is coated with liquid resin with use of a dispenser. After that, the liquid resin having undergone coating is molded with use of a compression mold machine. The liquid resin is thereafter hardened with use of a circulating hot air oven, for instance. Heat treatment conditions in the hardening are a heating temperature of 150° C. and a heating period of one hour, for instance. Thus, the first resin sealing portion 117 is formed.

### Resin Sealing Portion Thinning Step

In the resin sealing portion thinning step, the first resin sealing portion 117 is thinned. In the resin sealing portion thinning step as illustrated in FIG. 4D, specifically, the first resin sealing portion 117 is thinned by being ground with use of a back grinder for Si wafer so that the top surface of the side wall portion 115 is exposed. In the resin sealing portion thinning step, the first resin sealing portion 117 on a side of the second surfaces 113b of the first electronic components 113 is ground. The resin configuring the first resin sealing portion 117 may cause a warpage of the first compound component layer 100 which may result in a warpage of the compound component device 1 and thus an amount of grinding on the first resin sealing portion 117 is preferably as large as possible in a range that ensures maintenance of a given strength, for instance. In this step, however, the first resin sealing portion 117 is not ground so as to expose the first electronic components 113 (the first electronic components 113 are not ground, for instance). A thickness of the thinned first resin sealing portion 117 is 50 to 150 μm, for instance.

### Electronic Component Layer Precursor Producing Step

In the electronic component layer precursor producing step, the silicon base layer 182 and the electronic component bonding layer 172 are removed so that entirety of surfaces of the component electrodes 113d is exposed and an electronic component layer precursor is thereby produced. In the electronic component layer precursor producing step as illustrated in FIG. 4E, specifically, a first Si support (first silicon support) 184 is stuck on the first resin sealing portion 117 and the side wall portion 115. Specifically, the silicon base layer 182 described in relation to the silicon base layer preparing step is separately prepared as the first Si support 184. Subsequently, a bonding layer 174 (strictly, coating film of adhesive) is formed on the silicon base layer 182 by the method described in relation to the electronic component bonding step. After that, the first resin sealing portion 117 and the side wall portion 115 are stuck on the first Si support 184 so that ground surfaces of the first resin sealing portion 117 and the side wall portion 115 come into contact with the coating film and heating is carried out with application of pressures. Thus, the bonding layer 174 is formed by hardening of the coating film of adhesive and the first Si support 184 is placed on the ground surfaces of the first resin sealing portion 117 and the side wall portion 115 with the bonding layer 174 interposed therebetween.

A purpose of provision of the first Si support 184 is to prevent occurrence of a harmful effect (more specifically, decrease in strength or the like) due to thinness of layers in manufacturing processes, compared with conventional configurations, in following removal of the silicon base layer 182 and the electronic component bonding layer 172. As illustrated in FIG. 4F, the silicon base layer 182 and the electronic component bonding layer 172 are removed by being ground with use of the back grinder for Si wafer. Thus, an electronic component layer precursor 110′ is produced. Incidentally, the electronic component layer precursor 110′ is the electronic component layer 110 from which the electronic component layer piercing vias 119 are removed.

### Electronic Component Layer Precursor Bonding Step

In the electronic component layer precursor bonding step, as illustrated in FIG. 4H, electronic component layer precursors 110′, 210′ are bonded so that main surfaces 112′, 212′ of the two electronic component layer precursors 110′, 210′ on which component electrodes 113d, 213d are not exposed face each other and a pair of electronic component layer precursors 10″ is thereby produced. Incidentally, the pair of electronic component layer precursors 10″ is the inverted layer 10 from which the redistribution layers 120, 220 and the electronic component layer piercing vias 119, 219 are removed.

As illustrated in FIG. 4G, specifically, the electronic component layer precursor 110′ is initially placed so that the main surface 112′ is exposed. Specifically, a second Si support (second silicon support) 186 is stuck on the component electrodes 113d and the insulating portions 113e with the bonding layer 174 interposed therebetween. After that, the first Si support 184 and the bonding layer 174 are removed by being ground.

Subsequently, the electronic component layer precursor 210′ is produced as with the electronic component layer precursor 110′. Bonding by the bonding layer 130 is carried out so that the main surfaces 112′, 212′ of the two electronic component layer precursors 110′, 210′ on which the component electrodes 113d, 213d are not exposed face each other. After that, the second Si support and the bonding layer that support the electronic component layer precursor 210′ are removed by being ground. Thus, the pair of electronic component layer precursors 10″ is produced.

### Inverted Layer Precursor Producing Step

In the inverted layer precursor producing step, as illustrated in FIG. 4N, an inverted layer precursor 10′ is produced by formation of the electronic component layer piercing vias 119, 219 that pierce the side wall portions 115, 215 of the pair of electronic component layer precursors 10″ and formation of the redistribution layer 220 on a main surface (corresponding to the first main surface 211 of the electronic component layer 210) of the pair of electronic component layer precursors 10″ on which the component electrodes 213d are exposed. Incidentally, the inverted layer precursor 10′ is the inverted layer 10 from which the redistribution layer 120 is removed.

In the inverted layer precursor producing step, the electronic component layer piercing vias 119, 219 and the redistribution layer 220 can be produced with use of a photolithographic method. Production of the electronic component layer piercing vias 119, 219 and the redistribution layer 220 will be described with reference to a sectional view into which a portion B in FIG. 4H is enlarged.

FIG. 4I is an enlarged view of a portion corresponding to the portion B of FIG. 4H. Ditto for FIGS. 4J to 4M. As illustrated in FIG. 4J, photoresist film 290 having a pattern corresponding to a pattern of the electronic component layer piercing vias 119, 219 in plan view is formed. As illustrated in FIG. 4K, the side wall portions 115, 215 and the bonding layer 130 that exist in Z direction from a cavity 290f of the photoresist film 290 are selectively removed (etched) by exposure and development in this state. Etching is carried out with use of reactive ion etching (RIE) and laser irradiation, for instance. Thus, through-holes 115f, 215f, 130f are formed so that (a portion of an upper surface of) the bonding layer 174 is exposed. Herein, the through-hole 130f of the bonding layer 130 has a substantially oval shape in ZX section. That is because the material configuring the bonding layer 130 is more prone to be etched than the material configuring the side wall portions 115, 215. Thus, the conducting vias 119a having the substantially oval shape are formed in following formation of the electronic component layer piercing vias. After the through-holes 115f, 215f, 130f are formed, the photoresist film 290 is removed.

Subsequently, the electronic component layer piercing vias 119, 219 are formed in the through-holes 115f, 215f, 130f. As illustrated in FIG. 4L, specifically, the electronic component layer piercing vias 119, 219 are formed in the through-holes 115f, 215f, 130f by electroplating. With use of a dual damascene method (more specifically, Cu dual damascene method), the electronic component layer piercing vias 119, 219 are formed in the through-holes 115f, 215f, 130f by electrolytic plating (more specifically, electrolytic Cu plating). Thus, the electronic component layers 110, 210 are formed.

Subsequently, the redistribution layer 220 is formed. In formation of the redistribution layer 220, specifically, the dielectric film and the interconnections that have specified patterns are formed by the photolithographic method and the etching that have been described above, so that the redistribution layer 220 is formed as illustrated in FIG. 4M. FIG. 4M is an enlarged view of a portion C of FIG. 4N.

In the formation of the redistribution layer 220, the inorganic dielectric film (0.1 to 0.2 μm thick) can be formed with use of a chemical vapor deposition (CVD) method such as PECVD, for instance. The inorganic dielectric film may be formed in one or more layers. In case where the inorganic dielectric film is formed in four layers, for instance, SiO₂: 0.25 μm/Si₃N₄: 0.1 μm/SiO₂: 0.25 μm/Si₃N₄: 0.1 μm may be provided, for instance, in order of mention from a side of a main surface 211′ of the electronic component layer precursor 210′ on which the component electrodes 213d are exposed.

### Second Compound Component Layer Forming Step

In the second compound component layer forming step, the second compound component layer is formed. In the second compound component layer forming step as illustrated in FIG. 4O, specifically, the second electronic component 913 is electrically connected to the redistribution layer 220 by the solder 940. Subsequently, the second resin sealing portion 917 is formed by sealing of the second electronic component 913. Thus, the second compound component layer 900 is formed.

### Inverted Layer Producing Step

In the inverted layer producing step, as illustrated in FIG. 4P, the inverted layer 10 is produced by formation of the redistribution layer 120 on the other main surface (the first main surface 111 of the electronic component layer 110) of the inverted layer precursor 10′ that is located on a side opposed to one main surface (corresponding to the first main surface 211 of the electronic component layer 210) (of the pair of electronic component layer precursors 10″). The redistribution layer 120 can be formed as with the redistribution layer 220 described in relation to the inverted layer precursor producing step.

### Dicing Step

In the dicing step, as illustrated in FIG. 4P, the second Si support 186 and the bonding layer 174 are removed and the mother integrated body is individuated by dicing along broken lines. Thus, the compound component device 1 according to the first embodiment is manufactured.

### Second embodiment

### Configurations of Compound Component Device

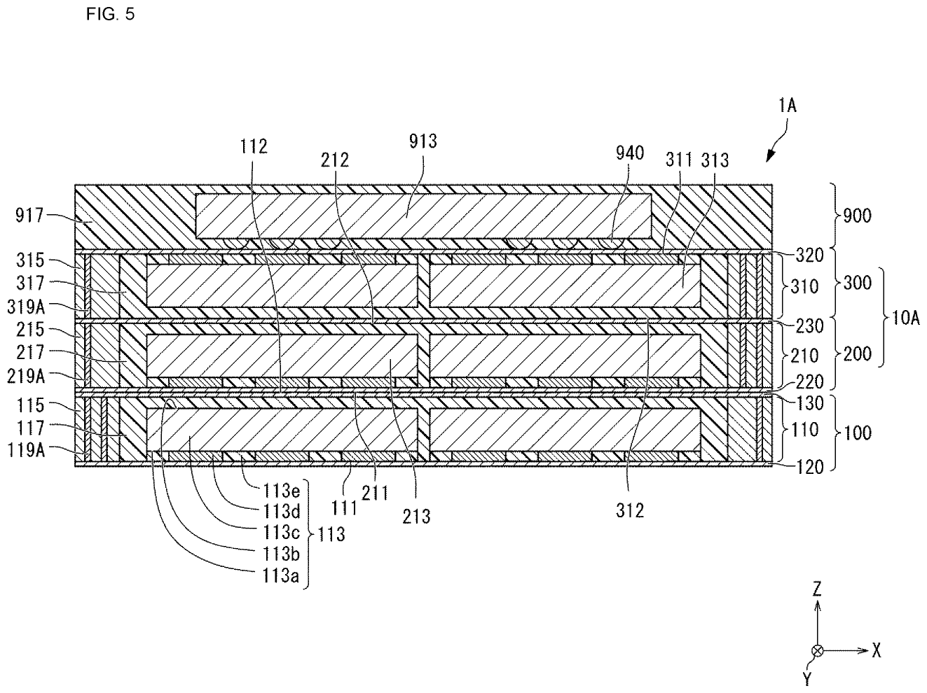

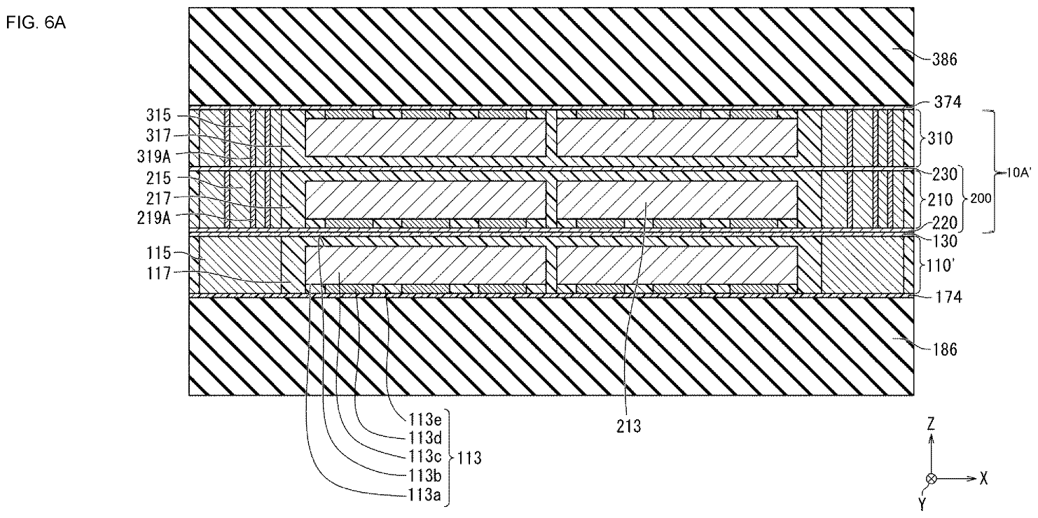

As illustrated in FIG. 5, a compound component device 1A according to a second embodiment differs from the compound component device 1 according to the first embodiment in further inclusion of the first compound component layer 100 that does not configure the inverted layer 10 and in a circuit pattern that electronic component layer piercing vias 119A, 219A, 319A have. These different configurations will be principally described below. As for the second embodiment, incidentally, reference characters that are the same as those of the first embodiment denote the same configurations as in the first embodiment and description thereof will be omitted in principle.

With reference to FIG. 5, configurations of the compound component device according to the second embodiment will be described. FIG. 5 is a diagram schematically illustrating a section of the compound component device 1A according to the second embodiment of the present disclosure.

An inverted layer 10A is placed on at least a center side with respect to a laminating direction for a plurality of first compound component layers 100, 200, 300. Herein, “placement on a center side” refers to placement in middle of a total number of layers (the first compound component layers 100, 200, 300 and the second compound component layer 900) that configure the compound component device 1A or placement in layers including middle layers. The inverted layer 10A includes the first compound component layers 200, 300 that are middle layers among the total number of layers of four and that are in second and third places from bottom of the compound component device 1A. Thus, the inverted layer 10A is placed on the center side in the compound component device 1A.

With this configuration, the inverted layer 10A whose internal stresses are prone to cancel out each other is placed on the center side in the compound component device 1A and thus the occurrence of a warpage is further curbed in the entire compound component device 1A.

Though the total number of layers is even in the second embodiment, “placement on a center side” will be further described herein with citation of a compound component device 1B having an odd total number of layers and according to a third embodiment (to be described later), as an example. The compound component device 1B includes five layers in total (four first compound component layers 100 to 400 and one second compound component layer 900). Accordingly, an inverted layer 10B includes the first compound component layers 300, 400 that include the first compound component layer 300 which is a middle layer and that are in third and fourth places from the bottom. Thus, the inverted layer 10B is placed on the center side in the compound component device 1B.

### First Compound Component Layer

The compound component device 1A according to the second embodiment further includes the first compound component layer 100 in addition to the inverted layer 10A including the first compound component layers 200, 300. The first compound component layer 100 is joined to the redistribution layer 220 of the first compound component layer 200 with the bonding layer 130 interposed therebetween on a side of the second main surface 112. In the compound component device 1A, the first compound component layer that does not configure the inverted layer 10A is placed as an outermost layer.

### Electronic Component Layer Piercing Via

The electronic component layer piercing vias 119A include side wall portion piercing vias piercing the side wall portion 115 and conducting vias (not illustrated) piercing the bonding layer 130. The electronic component layer piercing vias 119A are electrically connected to the redistribution layer 220 by the conducting vias. In a plane perpendicular to a thickness direction of the compound component device 1A, as with the first embodiment illustrated in FIG. 2, a cross-sectional area (cross-sectional area in XY plane) of the conducting via is larger than a cross-sectional area of the side wall portion piercing via. Thus, the electronic component layer piercing vias 119A have satisfactory electrical connections with the redistribution layer 220 and connection resistance between the first compound component layers 100, 200 is decreased. Accordingly, reliability of the compound component device 1A according to the second embodiment is further increased.

The electronic component layer piercing vias 119A, 219A, 319A are placed so as to be arranged on one straight line in at least one pair of adjoining first compound component layers among the plurality of first compound component layers 100, 200, 300. In the sectional (ZX section) view illustrated in FIG. 5, more particularly, the two electronic component layer piercing vias 219A, 319A are placed so as to be arranged on one straight line in the adjoining first compound component layers 200, 300. Further, the three electronic component layer piercing vias 119A, 219A, 319A are placed so as to be arranged on one straight line in the adjoining first compound component layers 100, 200, 300.

Therefore, the compound component device according to the present disclosure enables selection of an arrangement of the electronic component layer piercing vias in accordance with an application thereof and thus heightens the degree of freedom of design.

### Method of Manufacturing Compound Component Device

An example of a method of manufacturing the compound component device 1A according to the second embodiment will be described.

The method of manufacturing the compound component device 1A according to the second embodiment further includes, in addition to the method of manufacturing the compound component device 1 according to the first embodiment, for instance, a laminating step of laminating an electronic component layer precursor produced separately on the inverted layer precursor, and an interconnection forming step of forming the electronic component layer piercing vias and the redistribution layer in or on the laminated electronic component layer precursor.

That is, a step in which the laminating step and the interconnection forming step are combined is carried out one time in the method of manufacturing the compound component device 1A according to the second embodiment.

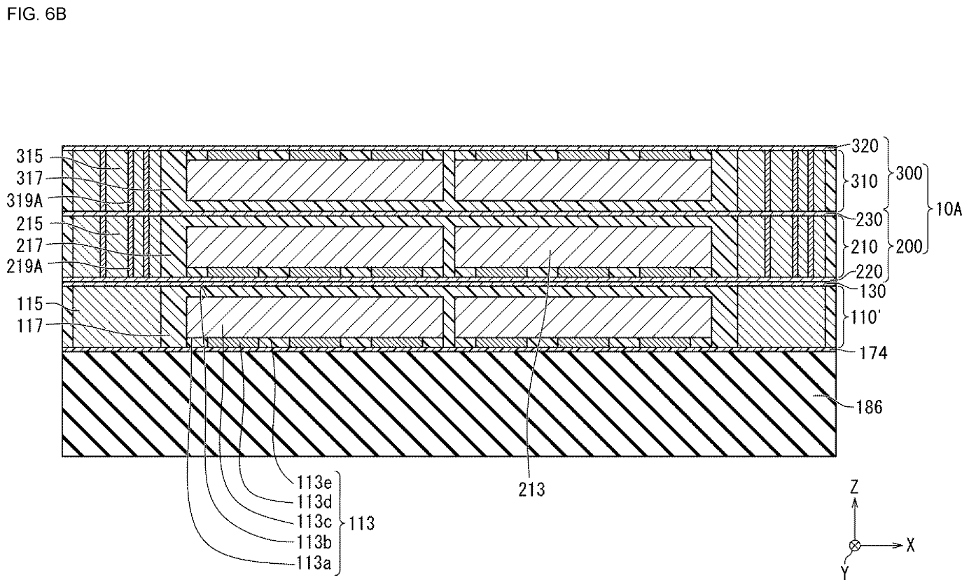

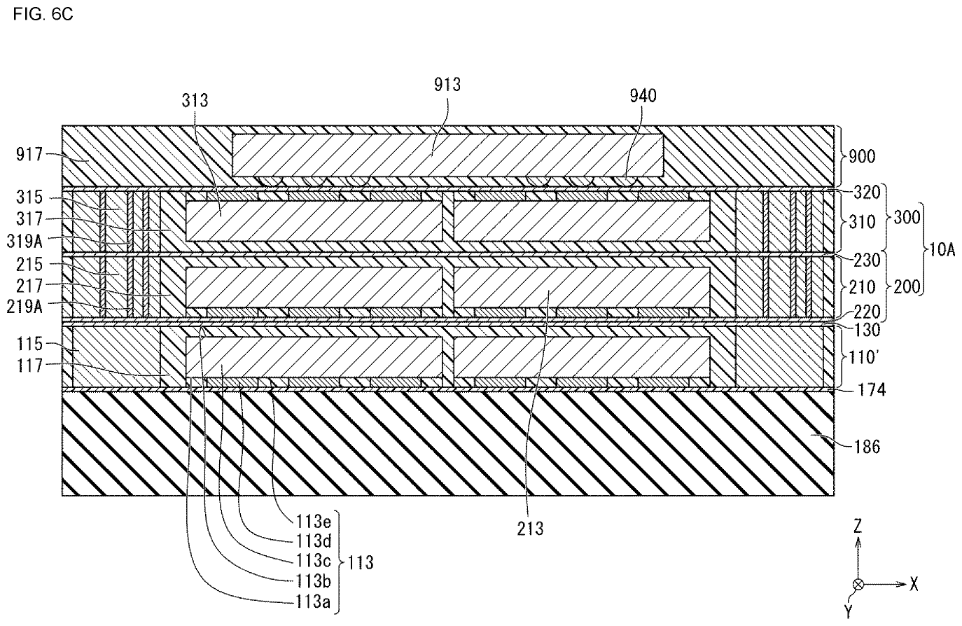

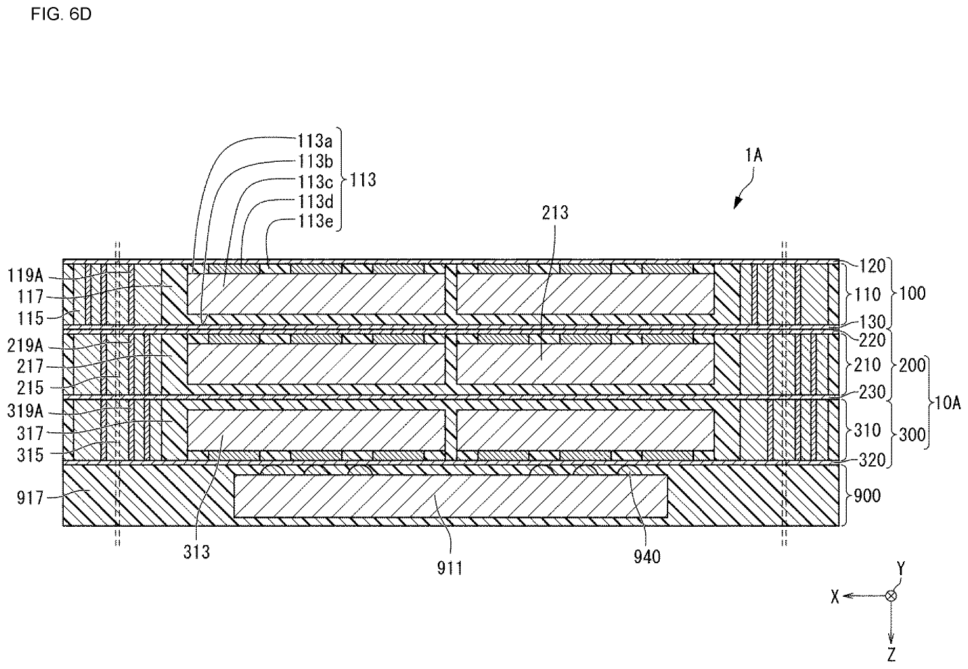

Specifically, an example of the method of manufacturing the compound component device 1A will be described with reference to FIGS. 6A to 6D. FIGS. 6A to 6D are diagrams for description of the method of manufacturing the compound component device 1A. The method of manufacturing the compound component device 1A according to the second embodiment includes the insulating portion forming step, the silicon base layer preparing step, the electronic component bonding step, the electronic component sealing step, the resin sealing portion thinning step, the electronic component layer precursor producing step, the electronic component layer precursor bonding step, the inverted layer precursor producing step, the laminating step, the inverted layer producing step, the second compound component layer forming step, the interconnection forming step, and the dicing step.

### Laminating step

In the laminating step, the electronic component layer precursor 110′ produced separately is laminated on the redistribution layer 220 of an inverted layer precursor 10A′. In the laminating step, specifically, the inverted layer precursor 10A′ is produced as with the first embodiment (refer to FIGS. 4A to 4N; however, there is a difference from the first embodiment in the circuit pattern of the electronic component layer piercing vias 219A, 319A). The electronic component layer precursor 110′ is stuck with the bonding layer 130 on a side of the redistribution layer 220 on the first compound component layers 200, 300 in the obtained inverted layer precursor 10A′. Herein, the electronic component layer precursor 110′ is separately produced as with the first embodiment (refer to FIGS. 4A to 4G). In the laminating step, in this manner, the electronic component layer precursor 110′ produced separately is laminated on the inverted layer precursor 10A′.

### Inverted Layer Forming Step

In the inverted layer producing step, as illustrated in FIG. 6B, the inverted layer 10A is produced by formation of a redistribution layer 320 on the other main surface (corresponding to a first main surface 311 of the electronic component layer 310) of the inverted layer precursor 10A′ that is located on the side opposed to one main surface (corresponding to the first main surface 211 of the electronic component layer 210) thereof.

In the inverted layer producing step as illustrated in FIG. 6B, specifically, a second Si support 386 and a bonding layer 374 are initially removed. Subsequently, the redistribution layer 320 is produced on the other main surface (corresponding to the first main surface 311 of the electronic component layer 310) exposed on the inverted layer precursor 10A′. Thus, the inverted layer 10A is produced.

### Second Compound Component Layer Forming Step

In the second compound component layer forming step as illustrated in FIG. 6C, the second compound component layer 900 is formed on the redistribution layer 320 (refer to the second compound component layer forming step of the first embodiment and FIG. 40).

### Interconnection Forming Step

In the interconnection forming step, the electronic component layer piercing vias 119A and the redistribution layer 120 are formed in or on the laminated electronic component layer precursor 110′. In the interconnection forming step as illustrated in FIG. 6D, specifically, the second Si support 186 and the bonding layer 174 are removed. Subsequently, the electronic component layer piercing vias 119A in the side wall portion 115 and the redistribution layer 120 on an exposed main surface 111′ of the electronic component layer precursor 110′ are formed. Herein, the electronic component layer piercing vias 119A are formed so as to extend to the bonding layer 130.

The compound component device 1A is manufactured through the dicing step.

### Third Embodiment

### Configurations of Compound Component Device

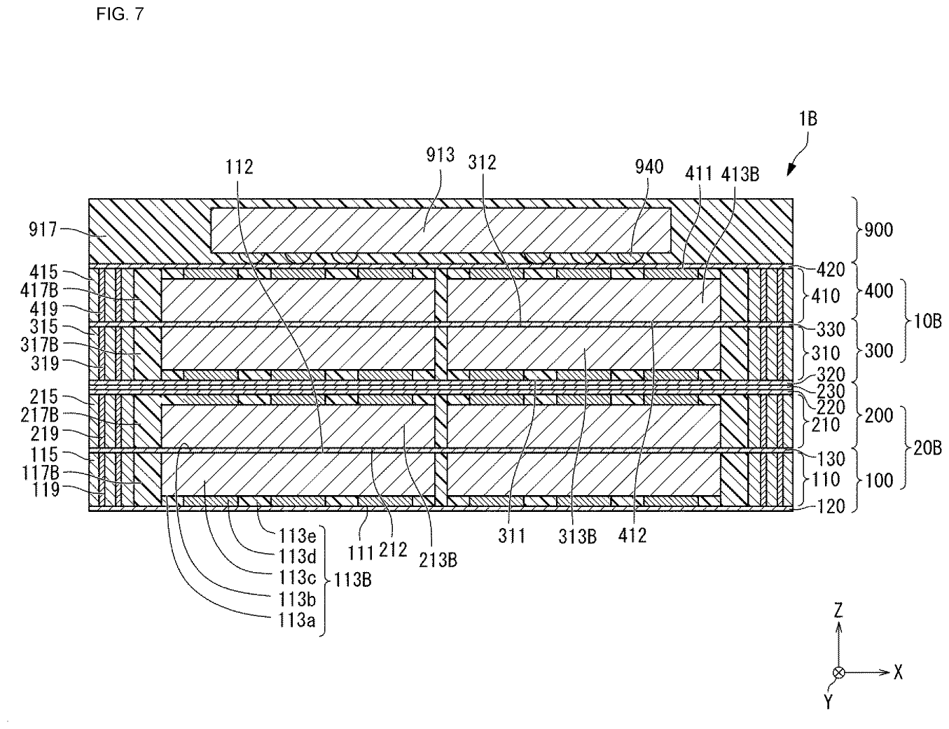

As illustrated in FIG. 7, the compound component device 1B according to a third embodiment differs from the compound component device 1 according to the first embodiment in further inclusion of the first compound component layers 100, 200 that configure an inverted layer 20B and in decreased amounts of resin of first resin sealing portion 117B, 217B, 317B, 417B. These different configurations will be principally described below. As for the third embodiment, incidentally, reference characters that are the same as those of the first and second embodiments denote the same configurations as in the first and second embodiments and description thereof will be omitted in principle.

With reference to FIG. 7, configurations of the compound component device according to the third embodiment will be described. FIG. 7 is a diagram schematically illustrating a section of the compound component device 1B according to the third embodiment.

### First Compound Component Layer, Inverted Layer

The compound component device 1B according to the third embodiment further includes the inverted layer 20B including the first compound component layers 100, 200 in addition to the inverted layer 10B including the first compound component layers 300, 400. The compound component device 1B includes the plurality of inverted layers 10B, 20B. By including the plurality of inverted layers 10B, 20B in which internal stresses in the first compound component layers 100, 200, 300, 400 are prone to cancel out each other, the compound component device 1B is capable of effectively curbing the occurrence of a warpage and thus enables further multilayer configuration of the first compound component layers. Therefore, the compound component device according to the present disclosure enables the adjustment of number of layers in accordance with an application thereof and thus heightens the degree of freedom of design.

The two adjoining inverted layers 10B, 20B of the plurality of inverted layers 10B, 20B are joined together with a bonding layer 230 interposed therebetween. Joining of the pair of adjoining inverted layers 10B, 20B with the bonding layer 230 interposed therebetween further decreases the internal stresses occurring in the inverted layers 10B, 20B and thereby enables further multilayer configuration of the first compound component layers. Therefore, the compound component device according to the present disclosure enables the adjustment of number of layers in accordance with an application thereof and thus heightens the degree of freedom of design.

The plurality of first compound component layers 100, 200, 300, 400 configure the even number of (specifically, two) inverted layers 10B, 20B and the even number of inverted layers 10B, 20B are symmetrical with respect to a center thereof in the laminating direction.

Herein, “symmetry” (“symmetrical”) means that configurations (more specifically, placement sites, numbers, types, dimensions, shapes, and the like of electronic component layers 110, 210, 310, 410, redistribution layers 120, 220, 320, 420, first electronic components 113B, 213B, 313B, 413B, side wall portions 115, 215, 315, 415, first resin sealing portions 117B, 217B, 317B, 417B, and electronic component layer piercing vias 119, 219, 319, 419) of the inverted layers 10B, 20B are in line symmetry with respect to an interface (corresponding to the bonding layer 230) between the laminated inverted layers 10B, 20B. For instance, it is meant that the electronic component layers 310, 410 configuring the inverted layer 10B are in line symmetry with the electronic component layers 110, 210 configuring the inverted layer 20B with respect to the bonding layer 230.

On condition that the even number of inverted layers 10B, 20B are symmetrical with respect to the center thereof in the laminating direction, the internal stresses occurring in the inverted layers 10B, 20B are prone to oppose and cancel out each other. In the compound component device 1B according to the third embodiment, therefore, the occurrence of a warpage is further curbed.

### Electronic Component Layer Piercing Via

The electronic component layer piercing vias 319 further include inter-inverted layer conducting vias (not illustrated) that pierce the bonding layer 230 joining the inverted layers 10B, 20B together to make electrical connections between the inverted layers 10B, 20B, in addition to side wall portion piercing vias that pierce the side wall portion 315 and conducting vias that pierce a bonding layer 330 to make electrical connections to the electronic component layer piercing vias 419.

In sections perpendicular to a laminating direction of the first compound component layers 100, 200, 300, 400, a cross-sectional area of the inter-inverted layer conducting via is larger than a cross-sectional area of the side wall portion piercing via. In such a configuration, the electrical connections between the inverted layers 10B, 20B are made by the inter-inverted layer conducting vias each having a larger connection area and thus the compound component device 1B has high reliability.

### First Resin Sealing Portion

The plurality of first compound component layers 100, 200 are joined together by the bonding layer 130 and the second surfaces 113b of the electronic component main body portions 113c are in contact with the bonding layer 130. That is, a first resin sealing portion 117B has no resin on a side of the second surfaces 113b of the electronic component main body portions 113c. In this manner, the amount of resin in which a warpage may occur is reduced, so that the occurrence of the warpage is further curbed in the compound component device 1B according to the third embodiment.

### Method of Manufacturing Compound Component Device

An example of a method of manufacturing the compound component device 1B according to the third embodiment will be described.

The method of manufacturing the compound component device 1B according to the third embodiment further includes, in addition to the method of manufacturing the compound component device according to the first embodiment, for instance, a laminating step of laminating a pair of electronic component layer precursors produced separately on the inverted layer precursor, an interconnection forming step of forming the electronic component layer piercing vias and the redistribution layer in or on the laminated pair of electronic component layer precursors, and a step in which the laminating step and the interconnection forming step are combined is carried out one time.

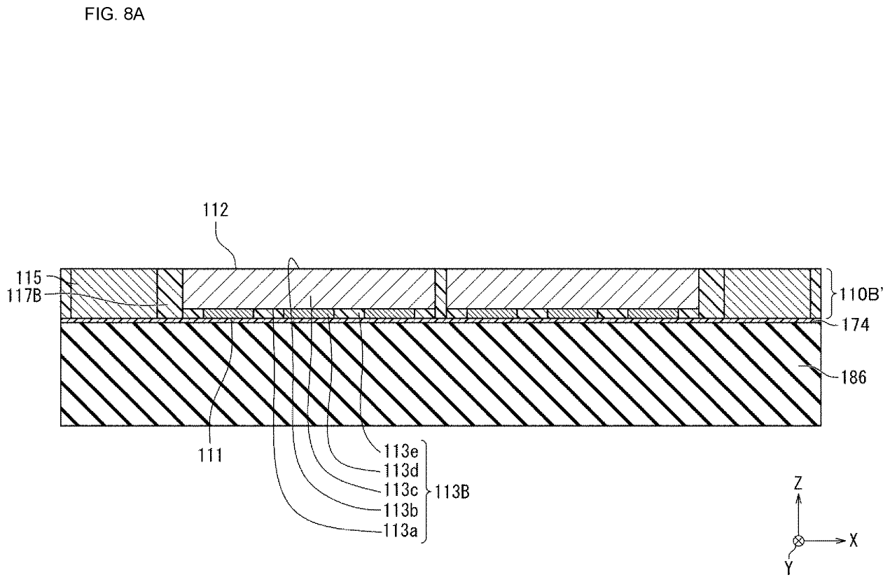

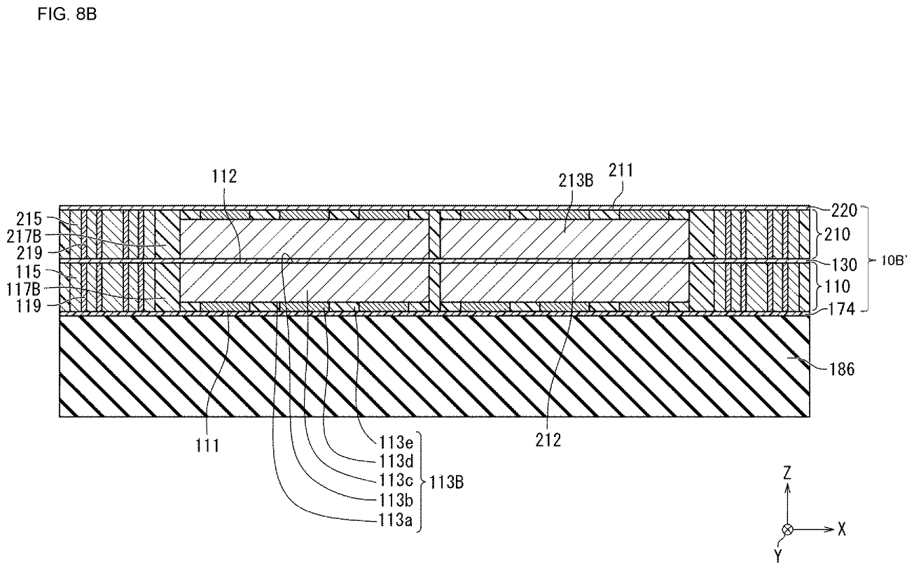

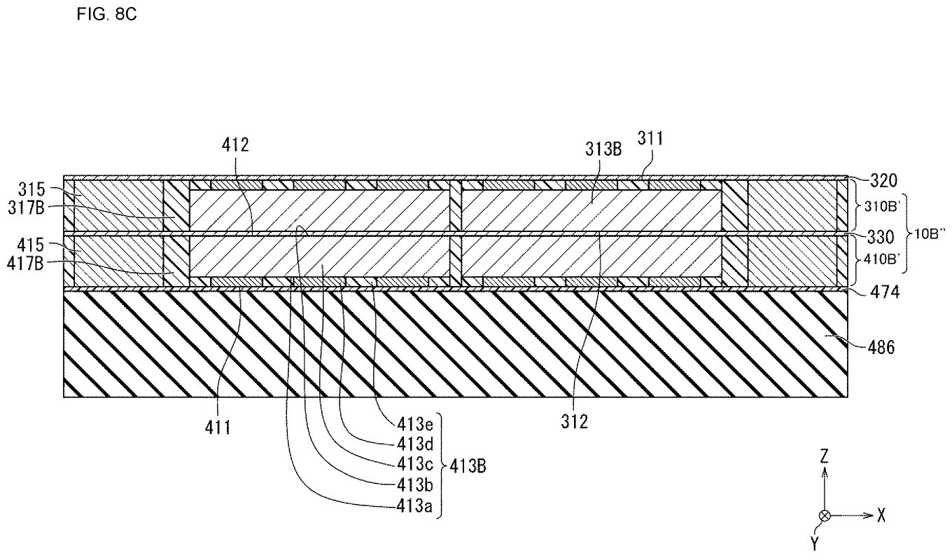

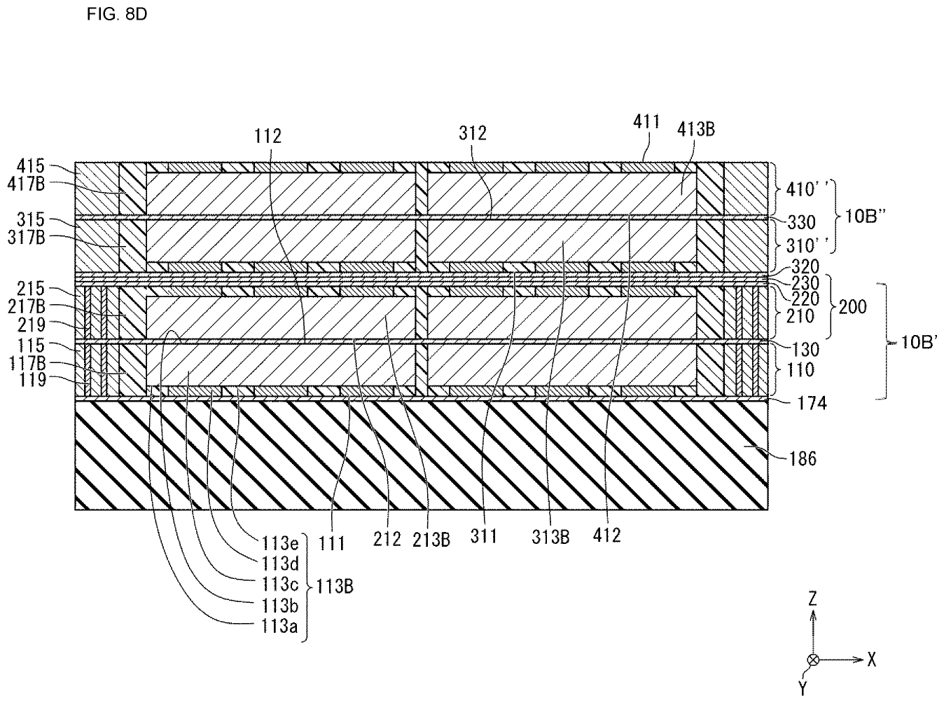

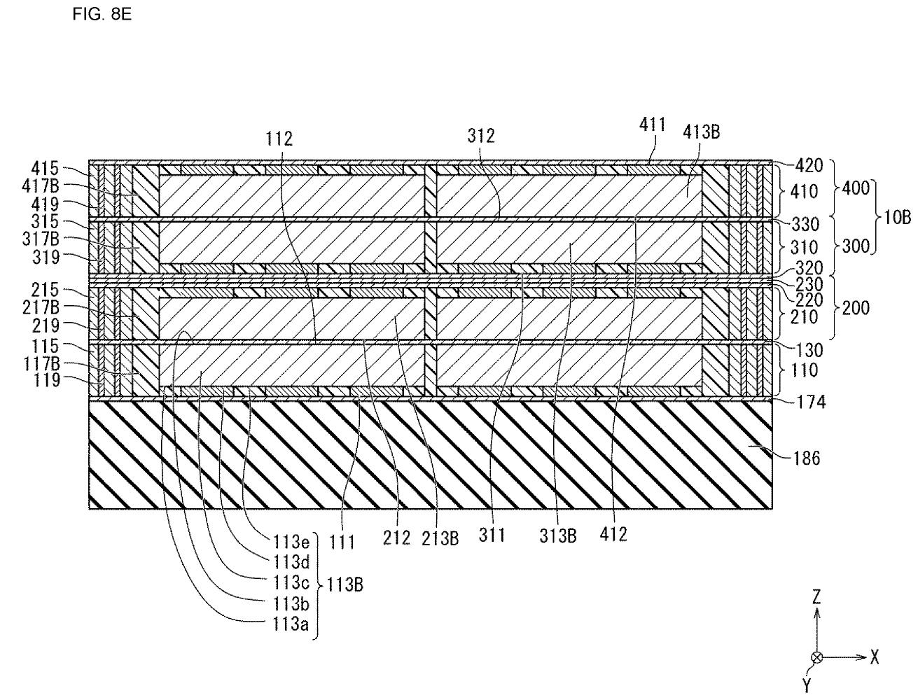

Specifically, an example of the method of manufacturing the compound component device 1B will be described with reference to FIGS. 8A to 8E. FIGS. 8A to 8E are diagrams for description of the method of manufacturing the compound component device 1B. The method of manufacturing the compound component device 1B according to the third embodiment includes the insulating portion forming step, the silicon base layer preparing step, the electronic component bonding step, the electronic component sealing step, the resin sealing portion thinning step, the electronic component layer precursor producing step, the electronic component layer precursor bonding step, the inverted layer precursor producing step, the laminating step, the interconnection forming step, the second compound component layer forming step, the inverted layer producing step, and the dicing step. In the method of manufacturing the compound component device 1B according to the third embodiment, incidentally, the step in which the laminating step and the interconnection forming step are combined is carried out one time.

### Resin Sealing Portion Thinning Step

In the resin sealing portion thinning step, as illustrated in FIG. 8A, the first resin sealing portion 117B is thinned until the first electronic components 113B are exposed. Herein, portions of the first electronic components 113B may be ground in addition to the first resin sealing portion 117B. Grinding, however, is carried out so that damage to the first electronic components 113B may be avoided. By thinning of the first resin sealing portion 117B until the first electronic components 113B are exposed, an amount of resin configuring the first resin sealing portion 117B can be reduced. Accordingly, the occurrence of a warpage in the compound component device 1B can be further curbed. Thus, an electronic component layer precursor 110B′ is produced.

### Inverted Layer Precursor Producing Step

In the inverted layer precursor producing step, as illustrated in FIG. 8B, an inverted layer precursor 10B′ is produced as with the first embodiment, except that electronic component layer precursors 110B′, 210B′ are employed in place of the electronic component layer precursors 110′, 210′ (refer to FIGS. 4A to 4N).

### Laminating Step

In the laminating step, as illustrated in FIG. 8D, a pair of electronic component layer precursors 10B″ produced separately is laminated on the inverted layer precursor 10B′. In the laminating step, specifically, the pair of electronic component layer precursors 10B″ is stuck on the side of the redistribution layer 220 on the first compound component layer 200 in the obtained inverted layer precursor 10B′, with the bonding layer 230. Herein, the pair of electronic component layer precursors 10B″ employs electronic component layer precursors 310B′, 410B′ produced in the inverted layer precursor producing step, as illustrated in FIG. 8C, and is separately produced as with the first embodiment, except that the redistribution layer 320 is further formed (refer to FIGS. 4A to 4G). In the laminating step, the pair of electronic component layer precursors 10B″ produced separately is thus laminated on the inverted layer precursor 10B′.

### Interconnection Forming Step

In the interconnection forming step, the electronic component layer piercing vias and the redistribution layer are formed in or on the laminated pair of electronic component layer precursors 10B″. In the interconnection forming step as illustrated in FIG. 8E, specifically, a second Si support 486 and a bonding layer 474 are removed. Subsequently, the electronic component layer piercing vias 419, 319 are respectively formed in the side wall portions 415, 315 and the redistribution layer 420 is formed on an exposed main surface (corresponding to a first main surface 411 of the electronic component layer 410) on the pair of electronic component layer precursors 10B″. Herein, the electronic component layer piercing vias 319 are formed so as to extend to the bonding layers 230, 330.

### Second Compound Component Layer Forming Step

In the second compound component layer forming step as illustrated in FIG. 7, the second compound component layer 900 is formed on the redistribution layer 420 (refer to the second compound component layer forming step of the first embodiment and FIG. 4O).

### Inverted Layer Forming Step

In the inverted layer producing step, as illustrated in FIG. 7, the inverted layer 20B is produced by formation of the redistribution layer 120 on the other main surface (corresponding to the first main surface 111 of the electronic component layer 110) of the inverted layer precursor 10B′ that is located on a side opposed to one main surface (corresponding to the first main surface 211 of the electronic component layer 210) thereof.

In the inverted layer producing step, specifically, the second Si support 186 and the bonding layer 174 are initially removed. Subsequently, the redistribution layer 120 is produced on the exposed main surface (corresponding to the first main surface 111 of the electronic component layer 110) of the inverted layer precursor 10B′. Thus, the inverted layer 20B is produced.

The compound component device 1B is manufactured through the dicing step.

### Other Embodiments

The present disclosure is not limited to the embodiments described above and design thereof may be modified to an extent not departing from purport of the present disclosure. Further, the configurations of the first to third embodiments may be combined variously.

Though the electronic component layer piercing vias 119 are provided to be placed with alignment in plan view (XY sectional view in FIG. 3) in the first embodiment, there is no limitation thereto. As illustrated in FIG. 10, for instance, electronic component layer piercing vias 119D may be provided in zigzag placement in a section perpendicular to the laminating direction for the plurality of first compound component layers 100, 200. Thus, the compound component device of the present disclosure enables selection of placement of the electronic component layer piercing vias 119, 219, 319 in accordance with an application thereof and thus heightens the degree of freedom of design.

Herein, “zigzag placement” refers to placement with arrangement at equal interval distances (which may be referred to as “distance L₂” below) on straight lines intersecting at an angle of 60° in plan view. On condition that a plurality of straight lines exist on one side configuring intersections at the angle of 60°, the plurality of parallel straight lines adjoin spaced apart by a distance L₂×\sqrt{3/2}. Therefore, the electronic component layer piercing vias 119D can be further integrated by the zigzag placement, compared with the placement with alignment.

In the first embodiment, the resin configuring the first resin sealing portion 117 of the one first compound component layer 100 may be different from the resin configuring the first resin sealing portion 217 of the different first compound component layer 200. In the second embodiment, among the resins that configure the first resin sealing portions 117, 217, 317 of the three first compound component layers 100, 200, 300, all the three may be different or two may be different. In the third embodiment, among the resins that configure the first resin sealing portions 117B, 217B, 317B, 417B of the four first compound component layers 100, 200, 300, 400, all the four may be different or three or two may be different.

Though the resins that configure the first resin sealing portions 117, 217 of the plurality of electronic component layers 110, 210 in the first embodiment are different (that is, the resins that configure the two first resin sealing portions 117, 217 are different), there is no limitation thereto. In the second embodiment, among the resins that configure the three first resin sealing portions 117, 217, 317, two resins or three resins may be different, for instance. In the third embodiment, among the resins that configure the four first resin sealing portions 117B, 217B, 317B, 417B, two to four resins may be different. Resins that differ in type may be employed for the first compound component layers in this manner and thus a particular resin type can be selected in accordance with an application for the compound component device. For instance, the compound component layers may be provided with respective different functions of the first resin sealing portions. Therefore, the compound component device according to the present disclosure heightens the degree of freedom of design.

Though the compound component devices 1, 1A, 1B of the first to third embodiments each include the two to four first compound component layers, there is no limitation thereto. For instance, the compound component device may include five or more first compound component layers. In the method of manufacturing the compound component device with such a configuration, the step in which the laminating step and the interconnection forming step are combined is carried out two or more times. In the compound component device according to the present disclosure, the configurations of the first compound component layers that are substantially identical curb complication of interconnection design and facilitate electrical connection between the first compound component layers. Therefore, the interconnections can be easily formed even if five or more first compound component layers are laminated. Accordingly, limitations on number, types, or the like of the first electronic components to be housed in circuit design are prone to be relieved and the degree of freedom of design is heightened. Therein, diverse circuit configurations are made available and a range of applications thereof is further broadened.

On condition that the step in which the laminating step and the interconnection forming step are combined is carried out two or more times in the method of manufacturing the compound component device, order of the laminating step, the inverted layer producing step, the second compound component layer forming step, and the interconnection forming step can be altered to such an extent that the compound component device can be manufactured, as described in relation to the second and third embodiments.

Though the compound component devices of the first to third embodiments each include the three electronic components in each of the first compound component layers, there is no limitation thereto. For instance, the compound component device may include one, two, or four or more first electronic components in each of the first compound component layers. Further, the compound component device may include a different number of first electronic components in each of the first compound component layers. Accordingly, limitations on number, types, or the like of the electronic components to be housed in circuit design are prone to be relieved and the degree of freedom of design is heightened. Therein, diverse circuit configurations are made available and a range of applications thereof is further broadened.

Though so-called face up method in which molding is carried out with direct coating with liquid resin on the silicon base layer 182 having the first electronic components 113 installed thereon is employed for the electronic component sealing step in the first to third embodiments, there is no limitation thereto. For instance, so-called face down method may be employed and the molding may be carried out with coating of a separate sheet with liquid resin and bonding thereto of the silicon base layer 182 having the first electronic components 113 installed thereon. Further, granular resin or sheet resin may be used in place of the liquid resin.

Though the bonding layer 174 is removed in the electronic component layer precursor bonding step in the first embodiment, there is no limitation thereto. Instead of removal of the bonding layer 174, entirety or a portion of the bonding layer 174 may be made to remain. On condition that the bonding layer 174 remains, smoothness of surfaces of the electronic component layer precursors can be improved. Thus, the redistribution layer 120 that more accurately reflets design can be formed.

Aspects of the compound component device and the method of manufacturing the compound component device according to the present disclosure are as follows.
<1> A compound component device including a plurality of laminated first compound component layers housing first electronic components, in which the first compound component layers each include an electronic component layer, including a first main surface and a second main surface opposed to the first main surface, and a redistribution layer provided on the first main surface. At least two of the plurality of first compound component layers configure an inverted layer for which the first compound component layers are paired and formed so that the second main surfaces face each other. The electronic component layer includes the first electronic component, a first resin sealing portion to seal the first electronic component, a side wall portion that is placed so as to enclose the first electronic component, and electronic component layer piercing vias to pierce the side wall portion and to electrically connect with the redistribution layer. The first electronic component is directly joined to the redistribution layer.
<2> The compound component device according to <1>, in which the redistribution layer includes dielectric film substantially made of inorganic material.
<3> The compound component device according to <1> or <2>, in which the side wall portion is substantially made of silicon.
<4> The compound component device according to any one of <1> to <3>, in which the electronic component layer includes a plurality of first electronic components per layer.
<5> The compound component device according to any one of <1> to <4>, in which resins that configure the respective first resin sealing portions of a plurality of the electronic component layers are different.
<6> The compound component device according to any one of <1> to <5>, further including a second compound component layer, as an outermost layer, including a second electronic component and a second resin sealing portion to seal the second electronic component.
<7> The compound component device according to <6>, in which the second compound component layer includes no side wall portion.
<8> The compound component device according to any one of <1> to <7>, in which the inverted layer is placed on at least a center side of the plurality of first compound component layers with respect to a laminating direction, and the first compound component layer that does not configure the inverted layer is placed as an outermost layer of the compound component device.
<9> The compound component device according to <1> or <2>, in which the electronic component layer piercing vias are provided in zigzag placement or in placement with alignment in a section perpendicular to a laminating direction of the first compound component layers.
<10> The compound component device according to any one of <1> to <9>, in which the electronic component layer piercing vias are provided so as to be substantially parallel to a laminating direction of the first compound component layers, and the electronic component layer piercing vias are placed so as to be arranged on one straight line in at least one pair of adjoining first compound component layers among the plurality of compound component layers.
<11> The compound component device according to any one of <1> to <10>, including a plurality of the inverted layers.
<12> The compound component device according to <11>, in which two adjoining inverted layers among the plurality of inverted layers are joined together with a bonding layer interposed therebetween.
<13> The compound component device according to <12>, in which the electronic component layer piercing vias include side wall portion piercing vias that pierce the side wall portion and inter-inverted layer conducting vias that pierce the bonding layer to make electrical connections between the inverted layers. Also, a cross-sectional area of the inter-inverted layer conducting via is larger than a cross-sectional area of the side wall portion piercing via in a section perpendicular to a laminating direction of the first compound component layers.
<14> The compound component device according to any one of <11> to <13>, in which the plurality of first compound component layers configure an even number of inverted layers, and the even number of inverted layers are symmetrical with respect to a center in a laminating direction of the even number of inverted layers.
<15> The compound component device according to any one of <1> to <14>, in which the first electronic component includes a first surface on which component electrodes are placed and a second surface opposed to the first surface, and the plurality of first compound component layers are joined together by a bonding layer. Also, the first electronic component includes component electrodes and an electronic component main body portion having a first surface on which the component electrodes are placed and a second surface opposed to the first surface, and the second surface is in contact with the bonding layer.
<16> The compound component device according to any one of <1> to <15>, in which the electronic component layer includes a plurality of first electronic components per layer, and the plurality of first electronic components are different.
<17> A method of manufacturing the compound component device according to any one of <1> to <16>, the method comprising an electronic component bonding step of bonding the first electronic component onto a silicon base layer so that component electrodes of the first electronic component come into contact with a bottom surface portion of the silicon base layer having a grid-like side wall portion and the bottom surface portion, with an electronic component bonding layer interposed therebetween; and an electronic component sealing step of forming a resin sealing portion by sealing of the first electronic component with resin. The method also comprises an electronic component layer precursor producing step of producing an electronic component layer precursor by removal of the silicon base layer and the electronic component bonding layer such that entirety of surfaces of the component electrodes is exposed; an electronic component layer precursor bonding step of producing a pair of electronic component layer precursors by bonding of the two electronic component layer precursors such that main surfaces of the two electronic component layer precursors on which the component electrodes are not exposed face each other; and an inverted layer precursor producing step of producing an inverted layer precursor by formation of electronic component layer piercing vias that pierce the side wall portions of the pair of electronic component layer precursors and a redistribution layer on one main surface of the pair of electronic component layer precursors on which the component electrodes are exposed. The method further comprises an inverted layer producing step of forming an inverted layer by formation of a redistribution layer on the other main surface of the inverted layer precursor that is located on a side opposed to the one main surface; a laminating step of laminating the pair of electronic component layer precursors produced separately and one of the electronic component layer precursors produced separately on the redistribution layer of the inverted layer precursor; and an interconnection forming step of forming electronic component layer piercing vias and a redistribution layer in or on the laminated pair of electronic component layer precursors and the laminated one of the electronic component layer precursors. In addition, a step in which the laminating step and the interconnection forming step are combined is carried out zero or more times.
<18> The method of manufacturing the compound component device according to <17>, in which the step in which the laminating step and the interconnection forming step are combined is carried out one or more times.

The compound component device according to the present disclosure can be installed in various types of electronic equipment in order to be utilized.

What is claimed is:

1. A compound component device comprising:
a plurality of laminated first compound component layers housing first electronic components, wherein
the first compound component layers each include an electronic component layer, including a first main surface and a second main surface opposed to the first main surface, and a redistribution layer on the first main surface,
at least two of the plurality of first compound component layers configure an inverted layer for which the first compound component layers are paired and configured so that the second main surfaces face each other,
the electronic component layer includes the first electronic component, a first resin sealing portion to seal the first electronic component, a side wall portion that encloses the first electronic component, and electronic component layer piercing vias that pierce the side wall portion and to electrically connect with the redistribution layer, and
the first electronic component is directly joined to the redistribution layer.

2. The compound component device according to claim 1, wherein
the redistribution layer includes dielectric film including inorganic material.

3. The compound component device according to claim 1, wherein
the side wall portion substantially includes silicon.

4. The compound component device according to claim 1, wherein
the electronic component layer includes a plurality of first electronic components per layer.

5. The compound component device according to claim 1, wherein
resins that configure the respective first resin sealing portions of a plurality of the electronic component layers are different.

6. The compound component device according to claim 1, further comprising:
a second compound component layer, as an outermost layer, including a second electronic component and a second resin sealing portion to seal the second electronic component.

7. The compound component device according to claim 6, wherein
the second compound component layer is absent a side wall portion.

8. The compound component device according to claim 1, wherein
the inverted layer is in at least a center of the plurality of first compound component layers with respect to a laminating direction, and
the first compound component layer that does not configure the inverted layer is an outermost layer of the compound component device.

9. The compound component device according to claim 1, wherein
the electronic component layer piercing vias are in zigzag configuration or configured in alignment in a section perpendicular to a laminating direction of the first compound component layers.

10. The compound component device according to claim 1, wherein
the electronic component layer piercing vias are substantially parallel to a laminating direction of the first compound component layers, and
the electronic component layer piercing vias are on one straight line in at least one pair of adjoining first compound component layers among the plurality of compound component layers.

11. The compound component device according to claim 1, comprising:
a plurality of the inverted layers.

12. The compound component device according to claim 11, wherein
two adjoining inverted layers among the plurality of inverted layers are joined together with a bonding layer interposed therebetween.

13. The compound component device according to claim 12, wherein
the electronic component layer piercing vias include side wall portion piercing vias that pierce the side wall portion and inter-inverted layer conducting vias that pierce the bonding layer to make electrical connections between the inverted layers, and
a cross-sectional area of the inter-inverted layer conducting via is larger than a cross-sectional area of the side wall portion piercing via in a section perpendicular to a laminating direction of the first compound component layers.

14. The compound component device according to claim 11, wherein
the plurality of first compound component layers configure an even number of inverted layers, and
the even number of inverted layers are symmetrical with respect to a center in a laminating direction of the even number of inverted layers.

15. The compound component device according to claim 1, wherein
the first electronic component includes a first surface on which component electrodes are present and a second surface opposed to the first surface, and
the plurality of first compound component layers are joined together by a bonding layer, and the second surface of the first electronic component is in contact with the bonding layer.

16. The compound component device according to claim 1, wherein
the electronic component layer includes a plurality of first electronic components per layer, and
the plurality of first electronic components are different.

17. A method of manufacturing the compound component device according to claim 1, the method comprising:
bonding the first electronic component onto a silicon base layer so that component electrodes of the first electronic component come into contact with a bottom surface portion of the silicon base layer having a grid-like side wall portion and the bottom surface portion, with an electronic component bonding layer interposed therebetween;
forming the first resin sealing portion by sealing of the first electronic component with resin;
producing an electronic component layer precursor by removal of the silicon base layer and the electronic component bonding layer such that entirety of surfaces of the component electrodes is exposed;
producing a pair of electronic component layer precursors by bonding of the two electronic component layer precursors such that main surfaces of the two electronic component layer precursors on which the component electrodes are not exposed face each other;
producing an inverted layer precursor by formation of electronic component layer piercing vias that pierce the side wall portions of the pair of electronic component layer precursors and a redistribution layer on one main surface of the pair of electronic component layer precursors on which the component electrodes are exposed;
forming an inverted layer by formation of a redistribution layer on the other main surface of the inverted layer precursor that is located on a side opposed to the one main surface;
laminating the pair of electronic component layer precursors produced separately and one of the electronic component layer precursors produced separately on the redistribution layer of the inverted layer precursor; and
forming electronic component layer piercing vias and a redistribution layer in or on the laminated pair of electronic component layer precursors and the laminated one of the electronic component layer precursors, wherein
one of the following:
the laminating and the forming of the electronic component layer piercing vias and the redistribution layer are performed separately; or
the laminating and the forming of the electronic component layer piercing vias and the redistribution layer are combined.

18. The method of manufacturing the compound component device according to claim 17, wherein
the laminating and the forming of the electronic component layer piercing vias and the redistribution layer are performed combined one or more times.

19. The compound component device according to claim 2, wherein
the side wall portion substantially includes silicon.

20. The compound component device according to claim 2, wherein
the electronic component layer includes a plurality of first electronic components per layer.
